(19) United States
(12) Patent Application Publication
(10) Pub. No.: US 2023/0270015 A1
(43) Pub. Date: Aug. 24, 2023

(54) PIEZOELECTRIC COMPOSITE FILM AND METHOD FOR MAKING SAME

(71) Applicant: SHIMCO NORTH AMERICA INC., Cambridge (CA)

(72) Inventors: DAYAN BAN, Waterloo (CA); ASIF ABDULLAH KHAN, Waterloo (CA); MD MASUD RANA, Waterloo (CA); GUANGGUANG HUANG, Waterloo (CA); YONGHUI ZHANG, Waterloo (CA); SHARIFUL ISLAM, Guelph (CA); PETER MICHAEL ROSS, Cambridge (CA)

(21) Appl. No.: 18/013,732

(22) PCT Filed: Jun. 29, 2021
(86) PCT No.: PCT/CA2021/050892

§ 371 Date: Dec. 29, 2022

Related U.S. Application Data
(60) Provisional application No. 63/102,752, filed on Jun. 30, 2020.

(51) Int. Cl. H10N 30/857; C08J 9/26; C08J 9/00; C08K 5/29; H10N 30/87; H10N 30/30

(52) U.S. Cl. CPC H10N 30/857; C08J 9/26; C08J 9/0028; C08K 5/29; H10N 30/30; H10N 30/87; C08J 2201/0442; C08J 2327/16; C08K 2201/011

(57) ABSTRACT

The present invention relates to a composite film that is capable of converting mechanical energy to electrical energy. The film comprises a substrate and piezoelectric nanoparticles that are configured to form a plurality of pores. The present film is flexible and highly porous, providing high permittivity and beneficial porosity-mediated mechanical properties. When used in a piezoelectric nanogenerator (PNG), the film provides enlarged bulk film strain and reduced film impedance, resulting in a high efficiency PNG with increased output voltage and current as compared to known PNGs. A method of synthesizing the film is also described. The provided method is simple and cost-effective.

### CROSS-REFERENCE TO RELATED APPLICATION

This application is a National Stage application, under 35 U.S.C. §371, of International Application No. PCT/CA2021/050892, filed Jun. 29, 2021, which claims the benefit under 35 U.S.C. §119(e) of U.S. Provisional Patent application serial No. 63/102,752, filed Jun. 30, 2020, the contents of which are hereby incorporated by reference.

### BACKGROUND OF THE INVENTION

### Field of the Invention

In one of its aspects, the present invention relates to a composite film, and more particularly to a piezoelectric composite film configured to comprise a plurality of pores. The device may be used, for example, as a power source for wireless data communication for personal electronics and energy harvesting from vibrations and biomechanical motion. The device may have application in structural health monitoring in aircrafts, space vehicles, implantable biomedical devices, and the like.

### Description of the Prior Art

Developing increasingly compact structures and high performing sustainable power sources has become an important area of research to assist in the deployment of self-powered electronics. Piezoelectric nanogenerators (PNGs), comprising flexible and compact structures, have emerged as possible candidates for this purpose.¹ For example, use of PNGs has been reported in self-powered nanoelectromechanical systems (NEMS), electronic/piezotronics devices, implantable medical devices, and remote sensing.²⁻⁸

Use of Self-Powered Structural Health Monitoring (SHM) to monitor the in-service conditions of aerospace systems has been reported.⁹ Such SHM systems have been reported to overcome the failure modes of traditional deficient time-based, high-cost scheduled maintenance, and thus may enhance the safety, consistency, and efficiency of aircraft structures.¹⁰

Wired sensor networks are currently an industry standard for aircraft SHM.¹¹⁻¹² Nevertheless, the installation of a wired network can be an error-prone process requiring significant manpower and costs. Alternatively, a wireless sensor network system can effectively eliminate wiring problems.¹³ For such wireless systems, a reliable and long-lasting power supply often becomes critical. One emerging technology for powering such wireless systems is a piezoelectric energy-harvesting device, which can harvest energy from the ambient environment.^{7,} 14

Energy harvesting technologies such as triboelectric¹⁵ and piezoelectric¹⁶⁻¹⁷ nanogenerators, and devices based on electromagnetic¹⁸⁻²² and electrostatic²³⁻²⁵ methods have been investigated for their ability to harvest ambient energies, such as energy from vibration, wind, raindrops, and ocean waves. Triboelectric nanogenerators (TENGs) have been reported to have high energy conversion efficiency, high output voltage, and flexible material selection, as well as being lightweight and low cost; ²⁶⁻³⁸ however, TENGs can suffer from a lack of durability and compactness, which can limit their SHM application, particularly in aircrafts. Piezoelectric nanogenerators (PNGs), on the other hand, have been reported to exhibit mechanical robustness, environmental adaptability, and sensitivity, suggesting potential for SHM applications.³⁹⁻⁴²

Numerous materials have been reported in the fabrication of PNGs, such as inorganic lead zirconate titanate (PZT), barium titanate (BaTiO3), zinc oxide (ZnO), Na/KNbO3, and ZnSnO3 nanoparticles, which have been reported to have large piezoelectric coefficients and high energy conversion efficiencies.^{39-43,106-108} Organic piezoelectric polymers, such as polyvinylidene fluoride (PVDF) and the copolymers hexafluoropropylene (P(VDF-HFP)) trifluoroethylene (P(VDF-TrFE)), and poly(vinyl acetate) (PVAc), have also gained attention because of their reportedly high flexibility, biocompatibility, simple material synthesis process, and the presence of am energy-efficient β-phase. ¹⁰⁹⁻¹¹³ However, intrinsic PVDF-based PNGs have yielded lower electrical energy outputs compared to their inorganic counterparts.¹¹⁴⁻¹²²

Altering the microstructures of piezoelectric films to enhance the strain-dependent piezoelectric polarization has been reported as an energy-harnessing mechanism. Strategies such as adopting nanowires,⁴³⁻⁴⁶ aspect ratio tuning, film porosity modulation through a multi-stage etching process,^{25,} ⁴⁷⁻⁵² cascading multiple devices,⁵³⁻⁵⁶ and reducing charge screening effects⁵⁷⁻⁶¹ are structure-driven techniques that have been reported to increase the piezoelectricity limit. For example, by creating pores in zinc oxide (ZnO) nanowires, Su et al. reported ~ 23-fold boosted output current in the PNGs (27.7 nA), with an elevated porosity percentage of 5.4%.⁴⁷ By using random and highly porous (50%) polyvinylidene fluoride (PVDF) structures (through an etching process), Mao et al. reported a PNG with an output voltage and current of 11.1 V and 9.7 µA, respectively, which is higher than those reported for a lithography assisted porous PVDF nanowire array.^{48,53} Yuan et al. reported a cascade-type six-layer rugby ball shaped PNG structure that increased output performance to 88.62 V_{PP} and 353 µA.⁵⁵

Although piezoelectricity has been reported to be enhanced by these strategies, optimally unifying appropriate mechanical and electrical properties in a single piezoelectric film can be a challenge. For example, among the piezoelectric materials, single crystals such as lead zirconium titanate (PZT), (1-x) Pb (Mg_{⅓} Nb_{⅔}) O₃⁻x PbTiO₃ (PMN—PT)⁶² possess a high piezoelectric coefficient (d₃₃); however, these materials can require high temperature material synthesis and be brittle. Lead-free piezoelectric materials may be more environmentally friendly but the reported output performance of such materials remains modest.⁶³

Dispersing highly piezoelectric nanoparticle (NPs) in a flexible polymer to form a film has been reported to improve fabrication scalability, device flexibility, mechanical strength, and electrical output.⁶⁴⁻⁶⁸ Nevertheless, in such reports, NP dispersion promoters had to be employed to improve the homogeneous dispersion of the NPs in the polymer scaffold, which can adversely impact device performance.⁶⁹⁻⁷⁴ Other researchers have reportedly addressed this issue by functionalizing the surface of piezoelectric NPs before mixing with the polymer⁷⁵ or by replacing NPs with organic-inorganic metal halide perovskites (OMHPs), such as uniformly distributed methylammonium lead iodine (MAPbI₃) or formamidinium lead halide (FAPbBr₃) in a PVDF or polydimethylsiloxane (PDMS) matrix; however, these films can still suffer from brittleness and scalability issues.^{40,41,76,77}

Despite the advances made to date in the development of piezoelectric films, there is room for improvement to address the above-mentioned problems and shortcomings of the prior art.

### SUMMARY OF THE INVENTION

It is an object of the present invention to obviate or mitigate at least one of the above-mentioned disadvantages of the prior art.

It is another object of the present invention to provide a novel film composite with piezoelectric potential.

Accordingly in one of its aspects, the present invention provides a film comprising a perovskite and a polymer, wherein the perovskite and the polymer are configured to form a plurality of elongated pores.

In another of its aspects, the present invention provides a process for producing a film comprising the steps of: (a) preparing a first solution by adding a polymer to a first solvent; (b) preparing a second solution by adding a perovskite to a second solvent; (c) homogenously mixing the first solution with the second solution to create a mixture; and (d) maintaining the mixture at a substantially constant temperature to crystalize the polymer and the perovskite.

In another of its aspects, the present invention provides a composite film comprising a substrate and a plurality of piezoelectric nanoparticles, wherein the substrate and the nanoparticles are configured to form a plurality of pores and wherein the composite comprises two opposed major surfaces interconnected by the pores.

Thus, the present inventors have developed a composite piezoelectric film comprising a substrate and piezoelectric nanoparticles configured to form a plurality of pores. This film is flexible and highly porous, providing high permittivity and porosity-mediated mechanical properties. When used in a PNG application, the film provides enlarged bulk film strain and reduced film impedance, resulting in a high efficiency PNG with increased output voltage and current as compared to other reported PNGs. With enhanced output performance and large area scalability, the present film is believed to have application as a compact, flexible power source in self-powered micro/nano wireless devices for harvesting mechanical energy from a range of environmental vibrations. The present inventors have also developed a simple, low cost process for preparing the film.

To the knowledge of the inventors, a film having such a combination of features are heretofore unknown.

Other advantages of the invention will become apparent to those of skill in the art upon reviewing the present specification.

### BRIEF DESCRIPTION OF THE DRAWINGS

Embodiments of the present invention will be described with reference to the accompanying drawings, wherein like reference numerals denote like parts, and in which:

FIG. 1 illustrates the characterization of a pure PVDF film. Scanning electron microscopy (SEM) image of (a) top surface of the pure PVDF (annealed at 75° C.); (b) the cross section of the pure PVDF film; (c) FTIR spectrum of the PVDF film (corresponding absorptions at the wavenumbers of 510 cm⁻¹, and 841 cm⁻¹).

FIG. 2 illustrates the characterization of an embodiment of the present film in which the film comprises ZnO-PVDF. (a) top surface SEM image of the PVDF loaded with ZnO nanoparticles (NPs) with a diameter of 35-45 nm; (b) cross sectional SEM image of the PVDF loaded with ZnO NPs. The SEM images are indicating that nanoparticles are not uniformly distributed rather accumulated in different positions of the PVDF film. This creates pores of different sizes after an etching process; (c) top surface SEM image of the porous PVDF film obtained after the etching of ZnO NPs by 37 wt. % hydrochloric acid (HCl); (d) atomic force microscopy (AFM) image of the porous PVDF surface; (e) measured surface roughness of the porous PVDF (100 nm).

FIG. 3 illustrates another embodiment of the present film in which the film comprises perovskite-polymer. The illustrated perovskite-polymer film comprises FAPbBr₂I-PVDF and is incorporated into piezoelectric nanogenerator (PNG). (a) fabrication process of the PNG; (b) XRD patterns of 20 wt. % FAPbBr₂I@PVDF of the present perovskite-polymer film; (c) FTIR results of porous PVDF film and 25 wt. % FAPbBr₂I@PVDF of the present perovskite-polymer film; (d) digital photos of the large area film (approximately 15 cm × 15 cm) and the fabricated PNG.

FIG. 4 illustrates (a) cross-sectional SEM image of the perovskite-polymer film (20 wt.% PVDF@FAPbBr₂I) of FIG. 3 (inset shows the close view of a pore); the corresponding element mapping of (b) fluorine in PVDF and (c) lead in the perovskite-polymer film; calculated (d) stress and (e) piezo potential distribution for a similar area of the pure PVDF film of FIG. 1, the 20% porous PVDF film of FIG. 2, and the perovskite-polymer film with 60% porosity (porosity induced by 20 wt. % of FAPbBr₂I) of FIG. 3.

FIG. 5 illustrates the morphology of pore structures in the perovskite-polymer film of FIG. 3. (a) cross-sectional SEM image of the perovskite-polymer film illustrating that the pores, with a length of 20-25 µm, are regularly distributed; (b) surface topography of the FAPbBr2I@PVDF film from the AFM image illustrating that the diameter of the pores are approximately 3-5 µm.

FIG. 6 illustrates the schematic illustration of crystallization process of the PVDF and FAPbBr₂I nanoparticles of the perovskite-polymer film of FIG. 3. The y-axis represents the total concentration of PVDF and FAPbBr2I in the solution; (b) schematic demonstration illustrating the interactions between FA⁺ cations and -CF2- groups. From the FTIR spectrum, this interaction is confirmed by the blue-shift of the infra-red absorption peaks of C-F bond in the wave number range of 1350-1100 cm⁻¹.

FIG. 7 illustrates the atomic force microscopy (AFM) images of the perovskite-polymer film of FIG. 3 with different mass ratios (wt. %) of FAPbBr₂I precursor solution in 10 wt. % PVDF precursor solution. (a) 5 wt. %; (b)10 wt. %; (c) 15 wt. %; (d) 20 wt. %; (e) 25 wt. %; (f) 30 wt. %; (g) grain boundary topology of FaPbBr₂I NPs (100 nm).

FIG. 8 illustrates the finite element simulation of the pure PVDF film of FIG. 1, the porous PVDF of FIG. 2, and the perovskite-polymer film of FIG. 3 under a compressive pressure of 800 kpa. (a) Finite element simulation of the pure film, porous PVDF film, and perovskite-polymer film under a compressive pressure of 800 kpa. The mechanical stress is calculated (b) along the horizontal axis (A-F) (c) along the vertical axis.

FIG. 9 illustrates a schematic characterization of piezo-potential distribution for the perovskite-polymer film of FIG. 3 (20 wt. % FAPbBr₂I@PVDF); with the presence of a single and an array of pore (8 pores) structures. The shape of the pores has been optimized from the observation of cross-section SEM image of the film. (a) Mechanical stress distribution of the film with the array of pores (left) and the film with a single pore (right) structure. The arrows are indicating the amplified stress on the sidewall of each pores. (b) The piezo-potential distribution is higher in the film with the presence of a large number of pore structures (left).

FIG. 10 illustrates the characterization system of the energy harvester. The controller unit is operated by a workstation interface (Vibration View 9). The controller unit (VR 9500) generates different control signals which are amplified by a power amplifier (Lab Works Inc.’s pa 138) to feed a electrodynamic shaker (ET-126-1) to control its motion. An accelerometer (3055D3) provides the feedback signal from the shaker to the controller unit which can take actions if there are any faults. The shaker is mechanically coupled with a metallic hammer to characterize the energy harvesting devices. The output from the devices are measured and viewed by an oscilloscope.

FIG. 11 illustrates the maximum output performance of the perovskite-polymer PNG of FIG. 3. (a) output voltage and (b) current of the perovskite-polymer PNG at 30 Hz and 2G acceleration with an applied load of 138 gram (g).

FIG. 12 illustrates the schematics of energy generation mechanisms of the perovskite-polymer PNG of FIG. 3 based on distributed stress profile.

FIG. 13 illustrates the variation of (a) output voltage and (b) output current of the perovskite-polymer PNG of FIG. 3, having different FAPbBr₂I mass ratios (0 wt.%, 10 wt.%, 20 wt.%, 30 wt. %).

FIG. 14 illustrates the output performance of PNGs. (a) V_{oc} and (b) I_{sc} of PNGs made from the pure PVDF of FIG. 1, the porous PVDF film of FIG. 2, and the perovskite-polymer film of FIG. 3. For the PGNs comprising the porous PVDF film and the perovskite-polymer film, the original mass ratios of particles inside the final films was 20 wt. %. (c) Polarization verification of the perovskite-polymer PNG by switching test; (d) relative permittivity of the PVDF PNG and the perovskite-polymer PNG; KPFM images of (e) porous ZnO- PVDF film and (f) the perovskite-polymer film.

FIG. 15 illustrates the frequency dependent output performance of the perovskite-polymer PNG of FIG. 3 with an input excitation from 10-50 Hz and 2G acceleration. The maximum output voltage and output current at 30 Hz frequency was 85 V and 30 µA, respectively. The gradual decrease in the output at higher frequencies (> 30 Hz) corresponds to the reduction of impact on the PNG by the 138 gram (g) proof mass.

FIG. 16 illustrates the flexibility test of the perovskite-polymer PNG of FIG. 3 at 10 Hz and 2G acceleration when a periodic bending force was applied from an electrodynamic shaker. The generated (a) output voltage (b) output current of 14 V and 0.3 mA, respectively, depicts the performance of the perovskite-polymer PNG during the bending condition.

FIG. 17 illustrates the framework of the self-powered integrated wireless electronics node (SIWEN) by simultaneously using the perovskite-polymer PNG of FIG. 3 as a power source and a sensor.

FIG. 18 illustrates the internal architecture of a self-powered integrated wireless electronics node (SIWEN). (a) functional block diagram of the SIWEN (b) internal circuit diagram of a LTC 3588-1 module (c) architecture of a RSL-10 system on chip (SoC).

FIG. 19 illustrates the application of the perovskite-polymer PNG of FIG. 3 for IoT (a). the measured output power of the perovskite-polymer PNG with an applied acceleration of 2 G (30 Hz). The used load was a metal block of 138 g; (b) charging characteristics of the input (1 µF) and output capacitor (220 µF) of the SIWEN; (c) the digital photo shows the sensor signal received by the cell-phone; (d) SIWEN used for car engine states detection at a parking condition (inset shows the corresponding frequency domain distribution via Fast Fourier Transform); (e) charging of a commercial capacitor (1 µF) by a single perovskite-polymer PNG while exciting by an automobile engine; (f) the corresponding digital photo of engine vibration detection.

FIG. 20 illustrates a structure design of another embodiment of the present film in which the film comprises porous PVDF. The illustrated film comprises porous PVDF and is incorporated into a PNG and functional wireless sensing circuit. (a) Schematic illustration of the functional components of the porous PVDF PNG, which is mainly comprised of PNG units and an integrated circuit unit; (b) an enlarge view of original circuit; (c) an as-fabricated PNG device; (d) The whole sensing system illustration with the aid of a block diagram.

FIG. 21 illustrates (a) an as-fabricated large scale embodiment of the porous PVDF film of FIG. 20 (approximately 15 cm x 15 cm); (b) Cross section Scanning Electron Microscopy (SEM) image of a pure PVDF film surface, annealed at 65° C.; (c) Cross sectional SEM image of distributed ZnO-NPs in the porous PVDF film.

FIG. 22 illustrates material properties characterization of the porous PVDF PNG illustrated in FIG. 20. Scanning electron microscope (SEM) images of (a) a pure PVDF film; (b) distribution analysis of ZnO NPs into the PVDF matrix of the porous PVDF film (inset is the film before etching); (c) top view SEM of the porous ZnO- PVDF film after etching of ZnO NPs (inset is the real film after etching); (d) surface morphology by AFM; (e) crystalline characterization of the PNG by Fourier transform infrared spectroscopy (FTIR) spectra to confirm β phase formation.

FIG. 23 illustrates the atomic force microscopy (AFM) image of the surface of the porous PVDF film of FIG. 20; (b) Measured surface roughness of the porous PVDF film.

FIG. 24 illustrates a schematic representation of the energy generation mechanism from the porous PVDF PNG of FIG. 20.

FIG. 25 illustrates measured experimental and simulated electric output performance of the porous PVDF PNG of FIG. 20. (a) peak to peak output voltage at 30 Hz frequency and 2G acceleration where the porous PVDF PNG top surface is weighted by standard mass of 138 gram; (b) peak to peak output current at 30 Hz frequency and 2G acceleration where the PNG top surface is weighted by 138 gram; (c) Stress distribution for 50 wt.% porous PVDF film; (d) Potential distribution for 50 wt.% PVDF porous film where the peak output voltage is 39.8 volt; (e) Polarity switch testing of short circuit current to confirm piezoelectricity; (f) Stability test of the porous PVDF PNG for 36000 cycles (30 Hz for 20 minutes).

FIG. 26 illustrates (a) prepared solutions of ZnO-PVDF with a ZnO mass ratio of 0 to 60 wt.% (0 and 50 wt% are not shown here); (b) the measured open-circuit voltage of the films comprising the prepared solutions of ZnO-PVDF of almost identical thickness when the ZnO mass fraction increased from 0% (pure PVDF) to 60%, with a frequency of 30 Hz.

FIG. 27 illustrates (a) stress distribution for a pure PVDF film and (b) potential distribution for a pure PVDF film where the peak output voltage is 10.9 volt.

FIG. 28 illustrates (a) the output short circuit current of the porous PVDF PNG of FIG. 20 (50 wt. %) with a range of frequencies from 10 Hz to 50 Hz and (b) the open-circuit voltage revealed identical amplitude with reversed polarization which confirmed the authenticity of the piezoelectric output signals.

FIG. 29 illustrates a demonstration of high output capability and applications prospect of the porous PVDF PNG device of FIG. 20 comprising a 50 wt.% porous PVDF film. (a) Comparison of output voltage at different frequencies from a wide range of 10 Hz to 50 Hz of the porous PVDF film; (b) Measured output voltage across various commercial capacitors of values 1 µF, 2.2 µF, 4.7 µF, 10 µF, 47 µF and 100 µF charged by the porous PVDF PNG excited at 30 Hz; (c) Measured output peak power and peak power density at loading condition of the porous PVDF PNG at frequency of 30 Hz; (d) Measured output voltage across the input and output capacitor of the EMM, when the porous PVDF PNG is excited with the linear motor shaking at 30 Hz; (e) Practical setup of Linear shaker where device is mounted on top of it and 138 gram mass on top of the porous PVDF PNG; (f) Signal transmission via Bluetooth™ device.

### DETAILED DESCRIPTION OF THE PREFERRED EMBODIMENTS

The present invention also relates to a film comprising a perovskite and a polymer, wherein the perovskite and the polymer are configured to form a plurality of elongated pores.

Preferred embodiments of this film may include any one of or a combination of any two or more of any of the following features:
the film comprises two opposed major surfaces interconnected by the pores;
the pores are at least partially vertically aligned to the two opposed major surfaces of the film;
the pores deform when a force is applied to a major surface of the film;
the pores are about 20 µm to 25 µm in length;
the pores are about 3 µm to about 5 µm in diameter;
the perovskite comprises nanoparticles;
the perovskite is embedded in the polymer;
the film comprises the perovskite in a crystalline form;
the perovskite crystal comprises a non-centrosymmetric structure;
the perovskite comprises a hybrid halide perovskite;
the perovskite comprises (HHP)-formamidinium lead bromine iodine (FAPbBr₂I);
the film comprises the polymer in a crystalline β-phase;
the polymer is selected from the group consisting of polyvinylidene fluoride (PVDF), polydimethylsiloxane (PDMS), polyvinylidene fluoride-trifluoroethylene (PVDF-TrFE), and polyethyl acrylate (PEA);
the polymer comprises polyvinylidene fluoride (PVDF);
the film comprises the perovskite in a mass ratio of about 10 wt. % to about 30 wt. %,
the film comprises the perovskite in a mass ratio of about 20 wt. %;
the film comprises the polymer in a mass ratio of about 10 wt. % to about 15 wt. %;
the film comprises the polymer in a mass ratio of about 10 wt. %;
the film comprises a plurality of dipoles, wherein said dipoles are substantially aligned;
the film has a thickness of about 20 µm to about 50 µm;
the film has a thickness of about 30 µm;
the film is formed by a two-step crystallization process;
a piezoelectric nanogenerator comprising the claimed film, a first electrode, and a second electrode, wherein the film is in electrical contact with the first electrode and the second electrode;
the claimed piezoelectric nanogenerator, wherein the first electrode comprises a metal or a polymer;
the claimed piezoelectric nanogenerator, wherein the first electrode comprises a metal selected from the group consisting of copper, gold, and aluminum;
the claimed piezoelectric nanogenerator, wherein the first electrode comprises poly(3,4-ethylenedioxythiophene) polystyrene sulfonate (PEDOT:PSS);
the claimed piezoelectric nanogenerator, wherein the second electrode comprises a metal or a polymer;
the claimed piezoelectric nanogenerator, wherein the second electrode comprises a metal selected from the group consisting of copper, gold, and aluminum;
the claimed piezoelectric nanogenerator, wherein the second electrode comprises poly(3,4-ethylenedioxythiophene) polystyrene sulfonate (PEDOT:PSS);
the claimed piezoelectric nanogenerator, wherein the nanogenerator is encapsulated by a substrate;
the claimed piezoelectric nanogenerator, wherein the substrate comprises polyester;
the claimed piezoelectric nanogenerator, wherein the nanogenerator is encapsulated using a thermal lamination process;
an aircraft structural health monitoring system incorporating the claimed piezoelectric nanogenerator;
a self-powered device incorporating the claimed piezoelectric nanogenerator; and
the claimed self-powered device, wherein the device is a wearable electronic device, a medical diagnostic device, or an implantable device.

The present invention also relates to a process for producing a film comprising the steps of: (a) preparing a first solution by adding a polymer to a first solvent; (b) preparing a second solution by adding a perovskite to a second solvent; (c) homogenously mixing the first solution with the second solution to create a mixture; and (d) maintaining the mixture at a substantially constant temperature to crystalize the polymer and the perovskite.

Preferred embodiments of this process may include any one of or a combination of any two or more of any of the following features:
the mixture is then casted and annealed to form a film;
the film is then poled using high voltage electrical poling;
the polymer crystalizes before the perovskite;
the first solution comprises the polymer in a mass ratio of about 10 wt. % to about 15 wt. %;
the first solution comprises the polymer in a mass ratio of about 10 wt. %;
the second solution comprises the perovskite in a mass ratio of about 10 wt. % to about 30% wt. %;
the second solution comprises the perovskite in a mass ratio of about 20 wt. %;
the first solvent is N,N-dimethylformamide;
the second solvent is N,N-dimethylformamide;
the mixture is maintained at a temp of about 60° C.;
the polymer is selected from the group consisting of polyvinylidene fluoride (PVDF), polydimethylsiloxane (PDMS), polyvinylidene fluoride-trifluoroethylene (PVDF-TrFE), and polyethyl acrylate (PEA);
the polymer comprises PVDF;
the perovskite comprises a hybrid halide perovskite;
the perovskite comprises FAPbBr₂I;
a film produced by the claimed process; and
a piezoelectric nanogenerator comprising a film produced by the claimed process.

The present invention also relates to a composite film comprising a substrate and a plurality of piezoelectric nanoparticles, wherein the substrate and the nanoparticles are configured to form a plurality of pores and wherein the composite comprises two opposed major surfaces interconnected by the pores.

Preferred embodiments of this composite film may include any one of or a combination of any two or more of any of the following features:
the substrate is a polymer;
the polymer is in a crystalline β-phase;
the polymer is PVDF;
the piezoelectric nanoparticles comprise a perovskite;
the perovskite comprises a hybrid halide perovskite;
the perovskite comprises (HHP)-formamidinium lead bromine iodine (FAPbBr₂I);
the pores are elongated;
the pores are at least partially vertically aligned to the two opposed major surfaces of the composite film;
the piezoelectric nanoparticles comprise zinc oxide (ZnO) nanoparticles;
the ZnO nanoparticles are randomly distributed throughout the composite film;
the composite film comprises the ZnO nanoparticles in a mass ratio of about 10 wt. % to about 50 wt. %
the composite film comprises the ZnO nanoparticles in a mass ratio of about 50 wt. %
the ZnO nanoparticles are about 25 nm to about 55 nm in diameter;
the ZnO nanoparticles are about 35 nm to about 45 nm in diameter;
the ZnO nanoparticles are distributed throughout the composite film by ultra-sonication;
the piezoelectric nanoparticles are removed from the composite film; and
a piezoelectric nanogenerator comprising the claimed composite film, a first electrode, and a second electrode, wherein the film is in electrical contact with the first electrode and the second electrode.

Preferred embodiments of the present invention will be described with reference to the following exemplary information which should not be used to limit or construe the invention.

### A. Perovskite-Polymer Composite Film

### 1. Experimental Methodologies

### 1.1 Synthesis of Films

### A. Pure PVDF Film

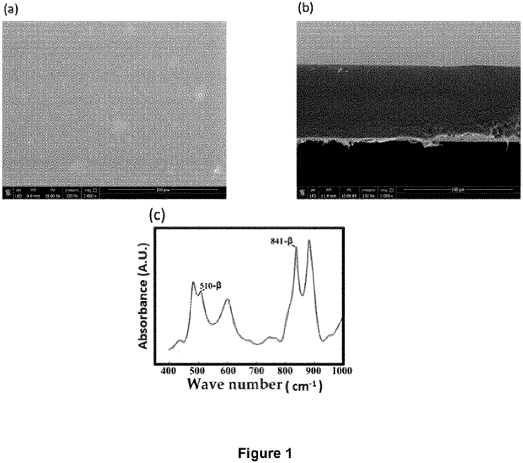

A pure or “solid” PDVF film was prepared. To prepare the PVDF solution, PVDF was purchased as a powder form (Sigma Aldrich) and was dissolved in N,N-dimethylformamide solvent (N, N-DMF; ≥ 99%, Sigma Aldrich) (10 wt. %) by stirring for 12 hours at 40° C. The temperature was maintained at 40° C. and was used to prevent agglomeration and achieve better dissolution. To prepare the PVDF film, the solution was drop-casted on a standard glass wafer that was placed on a flat hotplate. The sides of the glass substrates were covered with polyamide tape to prevent the solution from flowing outwards. Before starting the annealing process, the solution was kept under ambient conditions for 30 minutes for degassing. To form the spontaneous electroactive β-phase in the PVDF, the curing temperature was adjusted and maintained at 80° C. for 1 hour then the thin film (~ 40-50 µm) was peeled off from the glass substrate. The formation of the β-phase in the PVDF was confirmed by FTIR spectrum analysis (FIG. 1) and the surface morphology was investigated by using a scanning electron microscope (SEM) (FIG. 1). Finally, a high voltage electrical poling (50-120 V/µm) was performed for 2-4 hours to align the electric dipoles. For the high-voltage poling, two gold coated copper electrodes were prepared via the electroplating method. To minimize the negative influence of ambient moisture and the dust particles, the electrical poling was performed in a vacuum box. To make a PNG, the film was placed between two copper tapes and thermally laminated between two polyester substrates.

### B. Porous PVDF Film

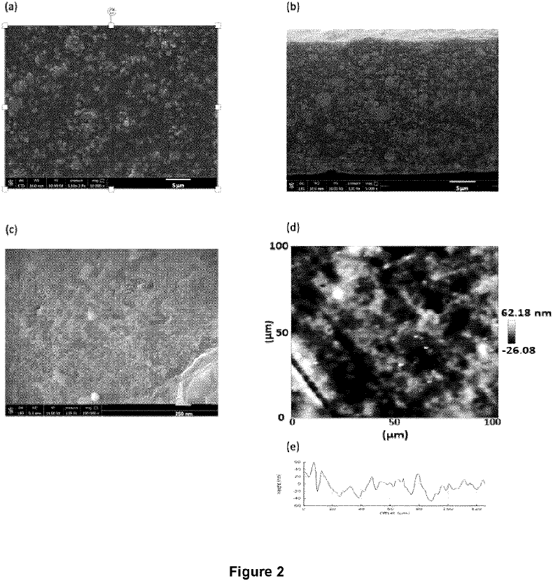

A porous PVDF film was prepared. PVDF powder was dissolved in N, N-DMF by stirring the solution for 12 hours at 40° C. To create different porosities, ZnO nanoparticles (NPs) (35-45 nm, US Research Nanomaterials, Inc.) were dispersed into the PVDF solution and stirred at 40° C. for 24 hours. The mass ratios between the PVDF and ZnO NPs (20 wt. %) were adjusted to create different pores inside the PVDF. To achieve a uniformly mixed ZnO-PVDF composite solution, the solution was further treated in an ultrasonic bath for 1 hour. The uniform solution was drop-casted onto a glass substrate and degassed for 30 minutes. The solution was cured at 75° C. inside a vacuum oven for 30 minutes. Afterward, the ZnO-PVDF film was peeled from the glass substrate (see FIG. 2 for the surface and cross-sectional morphology). To obtain the porosity inside the PVDF, one-step etching of the ZnO NPs was performed in an ultrasonic bath by immersing the ZnO-PVDF film in a 37 wt. % HCl solution for 4 hours. Then film was cleaned with DI water, and dried in a nitrogen filled oven at 60° C. for 3 hours (see FIG. 2 for the surface morphology). Finally, high-voltage electrical poling (50-120 V/µm) was performed for 2-4 hours to align the dipoles. To make a PNG, the film was placed between two copper tapes and thermally laminated between two polyester substrates.

### C. Perovskite-Polymer Film

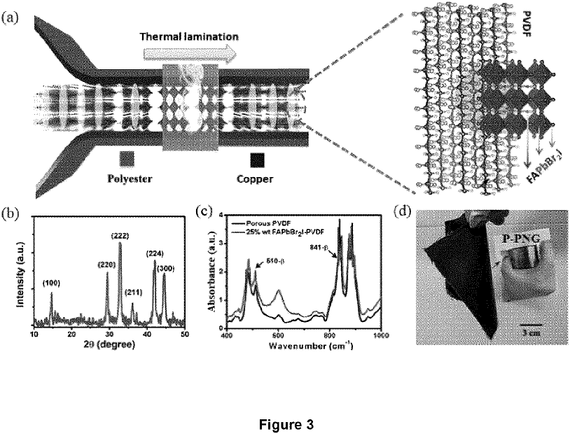

FIG. 3 illustrates an embodiment of the present composite film in which the film comprises perovskite nanoparticles and a polymer substrate. The perovskite can comprise any perovskite comprising crystals with a non-centrosymmetric structure, and preferably comprises (HHP)-formamidinium lead bromine iodine (FAPbBr₂I). The substrate is electrically insulating and can comprise a flexible polymer, such as polyvinylidene fluoride (PVDF), polydimethylsiloxane (PDMS), polyvinylidene fluoride-trifluoroethylene (PVDF-TrFE), or poly ethyl acrylate (PEA), and preferably comprises PVDF.

The solvent used for the precursor solutions must be capable of dissolving the perovskite and the polymer. Different solvents may be used for the perovskite precursor solution and the polymer precursor solution as long as each solvent can dissolve both the perovskite and the polymer. For example, the solvent may be N,N-DMF, dimethyl sulfoxide (DMSO), or tetrahydrofuran (THF), and is preferably N,N-DMF for both the perovskite precursor and polymer precursor solutions.

To prepare the perovskite-polymer film, a perovskite precursor solution was prepared by dissolving formamidinium iodide (FAI; ≥ 99%, Sigma-Aldrich) and lead (II) bromide (PbBr₂; ≥ 98%; Sigma-Aldrich) at an equal molar ratio (0.5:0.5) in an N,N-DMF (≥ 99%; Sigma-Aldrich), followed by stirring at 60° C. for 12 hours. A polymer precursor solution was prepared by dissolving PVDF in N,N-DMF with constant stirring at 50° C. for 24 hours. The final concentrations of FAPbBr₂I and PVDF in N,N-DMF were 20 wt. % and 10 wt. %, respectively.

Next, the perovskite-polymer composite solution was prepared by homogeneously mixing the perovskite precursor solution (20 wt. % FAPbBr₂I) with the polymer precursor solution (10 wt. % PVDF). To optimize the concentration, 10 wt. %, 20 wt. %, and 30 wt. % composite solutions were synthesized. The mixed solution was drop-casted onto a glass substrate and stored for approximately 1 hour for the degassing process. Immediately followed by annealing at 120° C., a crystalline film was obtained after 2-3 hours. To align the dipoles in the perovskite-polymer film, high-voltage electrical poling was completed with an electric field of 50-120 V/µm for 2-3 hours. For the high-voltage poling purpose, two gold coated copper electrodes were prepared via the electroplating method. To minimize the negative influence of ambient moisture and dust particles, the electrical poling was performed in a vacuum box.

### 1.2 Fabrication of Perovskite-Polymer Film Piezoelectric Nanogenerators (P-PNGs)

To prepare a perovskite-polymer film PNG, the perovskite-polymer film was sandwiched between two electrodes. The electrodes can be any suitable metal or polymer having a good conductivity and optimum work function, and preferably comprise copper, gold, aluminum, or poly(3,4-ethylenedioxythiophene) polystyrene sulfonate (PEDOT:PSS). In the present perovskite-polymer PNG, copper electrodes were used.

The wire connections were taken out from the top and bottom electrodes by 100 µm insulated copper conductors. The perovskite-polymer film and electrodes were then pressed through thermal lamination to eliminate air gaps and provide uniform adhesion between the copper electrodes and the perovskite-polymer film. The resulting structure was a polyester/copper/FAPbBr₂I-PVDF/copper/polyester PNG (see FIG. 3).

### 1.3 Characterization and Measurements

To investigate the crystallinity of the hybrid halide into the ferroelectric PVDF scaffold, X-ray diffraction (XRD) analysis was performed. Bruker D8 DISCOVER was used with Cu KR radiation source (λ = 1.54 ̊Å) to scan the optimized thin film samples (25 wt. % FAPbBr₂I-PVDF) from an angular range of zero to seventy degrees.

Fourier transform infrared spectroscopy (Nicolet iS50) was employed to confirm the ferroelectric β-phase formation inside a porous PVDF film and the perovskite-polymer film by measuring characteristic absorbance peak in a wavenumber range from 400 to 1000 cm⁻¹.

The dielectric property of the samples (C-V characteristics) was measured using the Keithley-4200 semiconductor parameter analyzer. JSM-7200F Field-emission scanning electron microscopy (JSM-7200F) tools were used to obtain surface morphologies and nanoparticle distribution inside the PVDF was mapped by analyzing energy dispersive X-ray in a cleanroom environment (Class-100). All of the atomic force microscopy (AFM) and Kelvin probe force microscopy (KPFM) images were captured by using JPK Nanowizard II, configured in intermittent-contact mode (scan rate 0.3 Hz). For the KPFM, imaging-cantilever (spring constant 42 N/m) with a platinum-coated tip (radius < 20 nm) was used to probe on a grounded sample. Constant tip-sample interaction was maintained with a phase-locked loop and the internal reference of the lock-in amplifier was an applied AC voltage (3 kHz) to the sample surface

To measure the electrical output performance of the perovskite-polymer PNG, an electrodynamic shaker (Lab works Inc.) was utilized, which was controlled by a power amplifier and a controller. A digital oscilloscope (Tektronix 2004 C) and a low-noise current preamplifier (Model- SR 570, Stanford Research System Inc.) were used to measure the electrical signal output from the PNGs.

### 2. Results and Discussion

### 2.1 Device Structure and Working Mechanism of P-PNG

FIG. 3 illustrates a schematic of an embodiment of the present perovskite-polymer film, wherein the perovskite-polymer film is fabricated into a PNG. As illustrated, in the final device fabrication step, the perovskite-polymer film is sandwiched between two copper electrodes and is encapsulated between polyester substrates through a thermal lamination process.

To elucidate the perovskite crystal formation inside the PVDF, XRD scans over a wide range (diffraction angle 2θ ranging from 10 to 50 degrees) were conducted. The major diffraction peaks are illustrated in FIG. 3, at diffraction angles (2θ) of 14.64, 29.43, 33, 42.12 and 44.39, which can be assigned to the (100), (220), (222), (224), and (300) crystal planes of a cubic perovskite structure, respectively.

Semi-crystalline PVDF polymer has four distinct phases (α,(β, γ, and δ) with (β-phase being the only phases that possesses the highest spontaneous polarization and the existence of (β-phase can be confirmed by the Fourier Transform Infrared (FTIR) spectrum. The FTIR spectrum illustrated in FIG. 3 demonstrates that, compared with a porous PVDF film,⁷⁸⁻⁷⁹ the present perovskite-polymer film has a higher intensity at a wavenumber of ~ 475 cm⁻¹, and a similar intensity at 840 cm⁻¹. While not wishing to be bound by any particular theory or mode of action, this result may be attributed to the improved (β-phase crystallinity of the PVDF, due to the existence of dipolar interactions between the FA⁺ cations of FAPbBr₂I and the anionic fluorine (-CF₂-) groups of the PVDF.⁸⁰⁻⁸¹

The piezoelectric coefficient (D₃) of the present films can be written as:

$${\text{D}}_{3} = {\text{α}}_{1} {\text{L}}_{\text{E}} \text{ϕ} {\text{d}}_{1} + {\text{α}}_{2} \left(1 - \text{ϕ}\right) {\text{d}}_{2} \qquad \text{(1)}$$

where α₁ and _{α2} are the poling rate, d₁ and d₂ are the piezoelectric coefficients of different materials in the film, respectively, L_{E} is the local field coefficient, and ϕ is the mass fraction. Assuming organic and inorganic phases are fully poled, i.e., α₁ = α₂ = 1, and ϕ = 0.2, the piezoelectric coefficient D₃ can be estimated. The local electric field (L_{E}= 3ε/ (2ε + ε_{c})) is related to the relative permittivity of the FAPbBr₂l nanoparticles (ε_{c}) as well as the film (ε). It has been reported that the ε_{c} can reach to 1000, which is much larger than ε. Therefore, L_{E} is estimated to be approximately 0.1-0.3.⁸² It has been identified that the piezoelectric coefficients of the PVDF and FAPbBr₂I phases are opposite. The approximated D₃ is calculated to be -23 pm/V when taking d₁ ~ 25 pm/V and d₂ ~-29 pm/V.⁴¹ Moreover, other factors such as the nanoparticles distribution and film geometry can also influence the piezoelectricity of the present film. The scalability of the present perovskite-polymer film ( approximately 15 cm × 15 cm) and a fabricated flexible perovskite-polymer PNG device are shown in FIG. 3. It was found that a small force applied to the PNG by the touch of a human hand was capable of generating sufficient energy to drive an LED (data not shown).

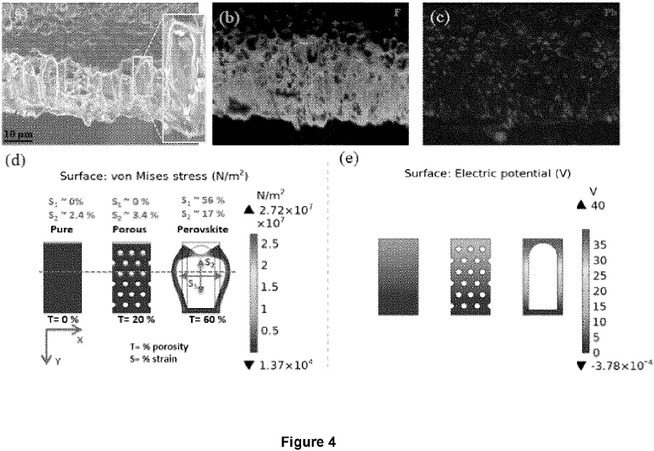

From the cross-section of the present perovskite-polymer film, as illustrated by the scanning electron microscopy (SEM) image in FIG. 4, an array of almost periodic vertical pores were observed. In contrast to a solid PVDF film and porous PVDF film (FIGS. 1 and 2), self-assembled and highly porous structures were found in the perovskite-polymer film.

The pores can be any length, and are preferably between about 15 µm to about 35 µm, and more preferably between about 20 µm to about 25 µm in length. The diameter of the pores can be any size, and is preferably between about 2 µm to about 8 µm, and more preferably between about 3 µm to about 5 µm.

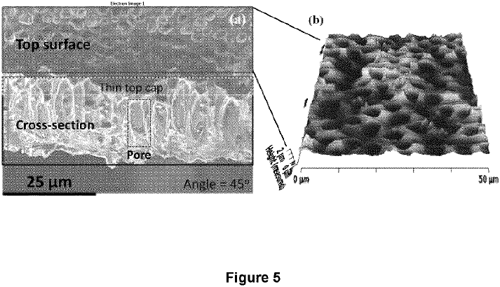

As illustrated in FIG. 5, the pores of the present perovskite-polymer film were ~ 20-25 µm in length (as illustrated in SEM image in FIG. 5) and ~ 3-5 µm in diameter (as illustrated in atomic force microscopy (AFM) image in FIG. 5).

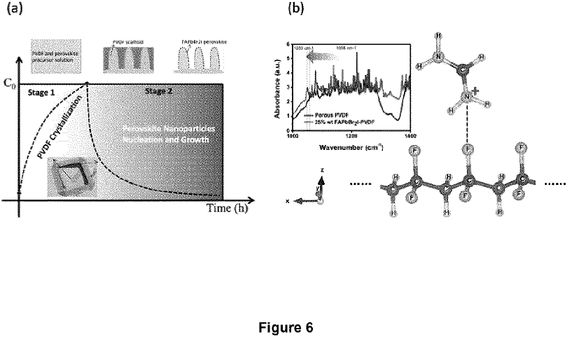

During the crystallization process, phase separation plays a role in the formation of the porous structures in the present perovskite-polymer film. As a result, the crystallization process can be divided into the following two stages.⁸³ During the first stage (schematic illustration in FIG. 6) (i) while heating the perovskite-polymer composite solution to 60° C., the N, N-DMF solvent starts to evaporate and the PVDF crystallizes due to its relatively lower solubility. Then it transforms to a colourless film and remains in an intermediate state. (ii) The FAPbBr₂I precursor solution portion of the perovskite-polymer composite solution then begins to approach to its supersaturated concentration (C₀) and forms into nanoparticles, which is indicated by the change in colour from colourless to red. While not wishing to be bound by any particular theory or mode of action, a key component of the self-assembly process of FAPbBr₂I nanoparticles embedding into the PVDF scaffold of the present perovskite-polymer film may be the two different crystallization processes of the PVDF and the FAPbBr₂I.

During the second stage, the perovskites nanoparticles tend to anchor on the PVDF scaffold. While not wishing to be bound by any particular theory or mode of action, this may be attributed to strong interactions between NH₃⁺ in the formamidinium (FA) cations of the FAPbBr₂I and -CF₂- groups of the PVDF. Such an interaction is reflected by the blue-shift of the infrared absorption peaks of C-F bond in the wave number range of 1350-1100 cm⁻¹ (FTIR spectrum illustrated in FIG. 6) due to the decreased force constant according to the expression of (v=1304√(k/u) (cm⁻¹), where v is the frequency, k the force constant (N/m), and u the effective mass. This interaction can also be observed from the mapping of the fluorine (F) atoms and lead (Pb) atoms, which correspond to the PVDF polymer chain (FIG. 4) and the FAPbBr₂I crystal (FIG. 4). As seen in FIG. 4, the perovskite clusters attach to the PVDF polymer. While not wishing to be bound by any particular theory or mode of action, this may be due to their common solubility in the N,N-DMF solvent (two materials can grow in one step) and the dipolar interactions between NH₃⁺ in FA (perovskite) and -CF₂- groups of the PVDF.

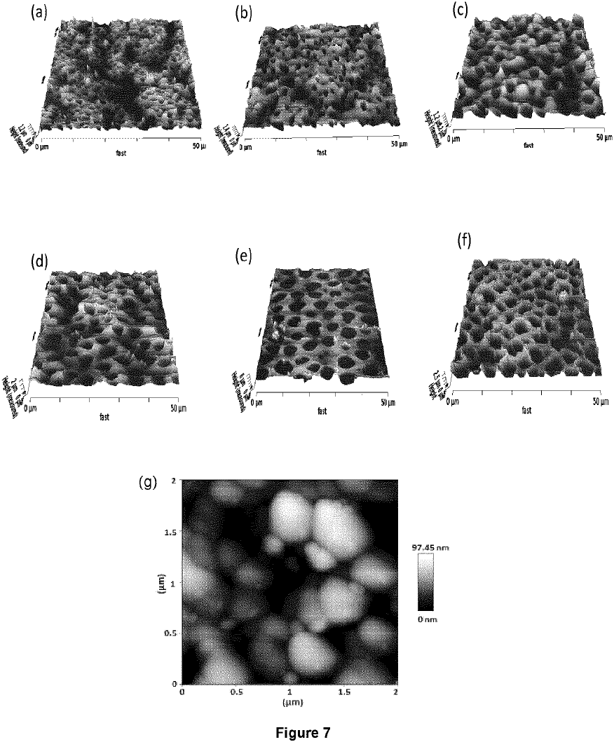

The porosity and size of the pores of the present perovskite-polymer film can be controlled via tuning the mass ratios (wt. %) of the perovskites with the polymer. The corresponding surface morphologies revealed in the AFM images (FIG. 7) illustrate that the pore diameter gradually increases to approximately ~ 7 µm at 30 wt. % of FAPbBr₂I. During the crystallization process, the increase in mass ratios should lead to the agglomeration of FAPbBr₂I NPs. While not wishing to be bound by any particular theory or mode of action, this may be attributed to the aforementioned strong dipolar interactions between the FA⁺ cations and the anionic fluorine (-CF₂-) groups of the PVDF.

A simulated perovskite-polymer PNG model was constructed to demonstrate the effects of the self-assembled highly-porous characteristics of the present perovskite-polymer film on the output piezo-potential. This was simulated using COMSOL Multiphysics 5.3. The simulation results were compared with those of pure (solid without pores) PVDF films and 20% circular shaped porous PVDF films (circular shapes were adopted from the ZnO NPs). FIG. 4 illustrates that, under uniaxial compressive stress of 800 kPa, the induced displacement of the three different PNG models (the same film thickness of 30 µm) is different. As illustrated in FIG. 4, the pure PVDF film is the least deformed, whereas the perovskite-polymer film is the most deformed. While not wishing to be bound by any particular theory or mode of action, pore position and size may influence the mechanical stress distribution, which may contribute to the increase in the average stress distribution profiles inside the perovskite-polymer film.

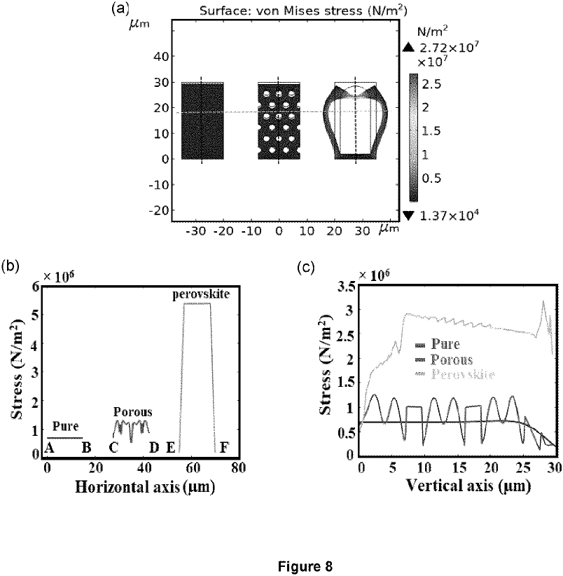

From the finite element calculation (along the cut lines in FIG. 8), the stress inside the pure PVDF film appears quite uniform under uniaxial vertical stress. In contrast, in the circular porous PVDF structure, the stress distribution is asymmetric in nature. Compared to the pure PVDF, the stress distribution in the circular porous PVDF model is disrupted by the presence of pores. In such circular porous structures (the middle model of FIG. 4), the stress is mainly confined around each pore but is higher along the direction of the applied force, namely, at the top and bottom sides of the pore. The localized compressive strain of each pores results in a bulk film strain mainly in the vertical direction (x-direction strain S₁ ~ 0%, y-direction strain S₂ ~ 3.4%) and modifies the internal coupling. The highly ordered porous structure of the present perovskite-polymer film (the right most model of FIG. 4) is not only deformed along the vertical direction (S₂ ~ 17%) but also significantly elongated along the horizontal direction (S₁ ~ 57%). The stress concentration spots at the top exert a pushing force on the pores of the perovskite-polymer film, inducing a relaxing strain on the two sides. FIG. 8 (the right most model) illustrates the linear stress-enhancing characteristics of this larger pore to the sidewall of the structure. This phenomenon is similar to the flex-tensional mechanism,⁸⁴_{′}⁸⁵ which underlines the structural modification of the mechanical body that could further amplify the applied vertical stress into the horizontal direction

Since the strain-induced piezo potential is a collective outcome from the strains around each of the pores, the piezoelectric potential in the porous PVDF structure is therefore higher (FIG. 4) than that in the non-porous PVDF piezoelectric films. The vibration-induced electric displacement D₃ (charge per unit area) is calculated by:

$${D}_{3} = {e}_{333} {S}_{33} + \left|{e}_{331}\right| {S}_{31} \qquad \text{(2)}$$

Where e₃₃₁ and e₃₃₃ are the piezoelectric constants⁸⁶ and S₃₁ and S₃₃ are induced strains along the horizontal and vertical directions, respectively. D₃ of the perovskite-polymer film is synergistically influenced by the bidirectional (horizontal and vertical) strains S₁ (~ 57%) and S₂ (~ 17%). Therefore, the perovskite-polymer film structure greatly increases the strain-induced piezo-potential or voltage output (according to the parallel plate capacitor model, V = Q/C, where Q is the total induced charge and C is the device capacitance), which was confirmed by the finite element simulation in FIG. 4, which illustrates the maximum piezoelectric potential of ≈ 40 V for the perovskite-polymer film, vs. ~ 11 V and ~ 15 V for pure and 20% porous PVDF films, respectively (with the same applied stress of 800 kPa).

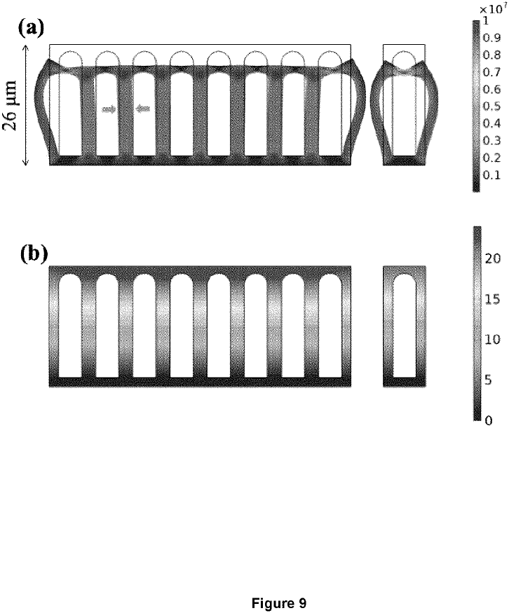

It should be noted that a perovskite-polymer PNG with an array of such highly ordered pores as illustrated would likely generate even higher potential than a structure having a single pore (the right most model in FIG. 9). In the array of pores, the wall of the inner pore structures are highly compressed due to the bidirectional stress (indicated by the arrows in FIG. 9). Between the interpore distance, the boosted stress further improves the piezoelectric potential of the perovskite-polymer film. Yuan et al. reportedly enhanced the piezo potential of a six-layer PVDF-TrFE (trifluoro ethylene) based PNG by 2.2 times by making a rugby-ball-shaped PNG structure to utilize the flex-tensional strain effect.⁵³ While not wishing to be bound by any particular theory or mode of action, the improved piezoelectric output of the present perovskite-polymer film may be attributed, at least in part, to this amplified mechanical strain.

### 2.2 Energy Harvesting Performance of the P-PNGs

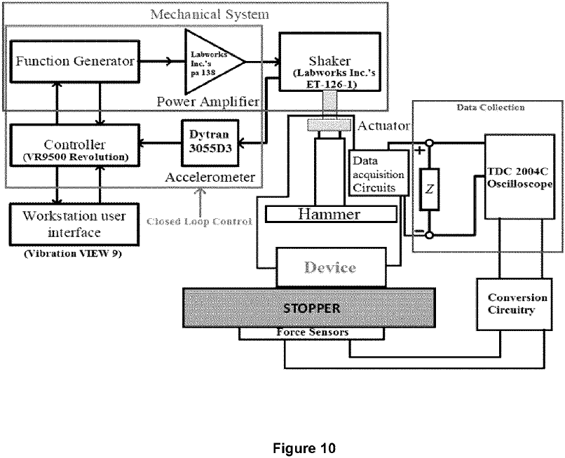

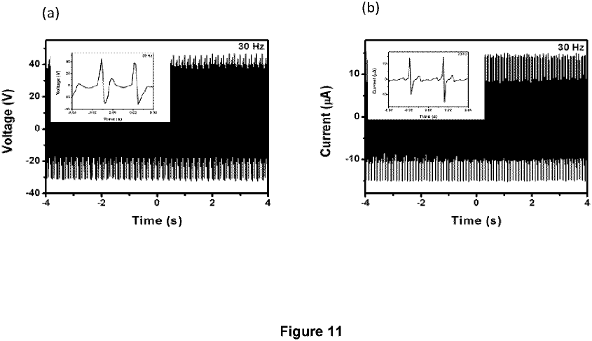

The present perovskite-polymer film provides a platform for developing scalable PNGs, which only require two thin metal electrodes on either side. Exploiting the perovskite-polymer film’s micro structure features along with the formation of FAPbBr₂I nanocrystals, the effect on PNG performance was investigated. The fabricated device was placed on the hammer of an electrodynamic shaker and sandwiched by a 138 g metal block (stainless steel) on top (schematic of testing set-up illustrated in FIG. 10). The generated output voltage and current were measured from the periodic mechanical vibration produced by the electrodynamic shaker at various frequencies (10-50 Hz) and accelerations (1-2.5 G). An output voltage of ~ 85 V (peak to peak) and short-circuit current of ~ 30 µA (peak to peak) were recorded from an active device area of 3.8 cm × 3.8 cm at 30 Hz and 2G (results illustrated in FIG. 11).

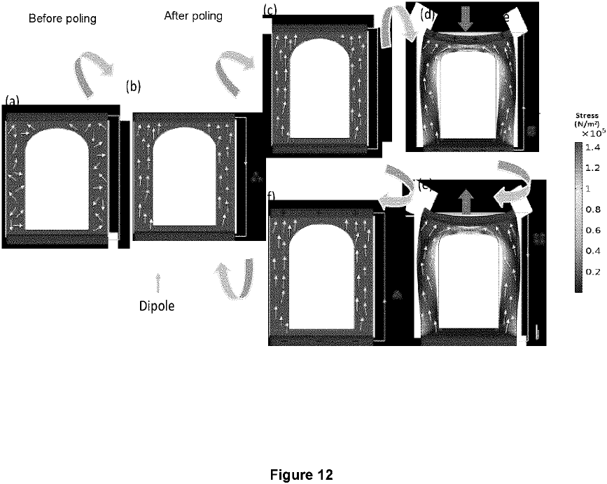

While not wishing to be bound by any particular theory or mode of action, FIG. 12 illustrates a working mechanism of a PNG comprising the present perovskite-polymer film, where the electricity generation mechanisms of the PNG are schematically illustrated from stress mapping by employing finite element simulation (COMSOL Multiphysics 5.3). When there is no applied electric field, the net dipole moment inside the film is almost zero (FIG. 12). By applying a high electric field (50-120 V/µm) for 2-3 hours, dipoles are aligned to the direction of the electric field (FIG. 12). If a compressive force is then applied to the device, the net polarization changes in the film due to the flex-tensional strain, thus producing piezoelectric potential (FIG. 12). It may be expected that due to a rapid change in the net dipole moment by the flex-tensional mechanism, a polarization change in the poled PNG can yield an even higher potential.⁸⁷⁻⁸⁸ If the two electrodes are connected to each other, then an electric current will flow to balance this piezo potential. While releasing the force, the piezo potential returns to zero because of the diminished film strain, and then the accumulated electrons will flow back (FIG. 12). Due to the formation of larger porous structures, the perovskite-polymer film could undergo an additional damping cycle, leading to the observation of a second output current pulse (FIG. 12).

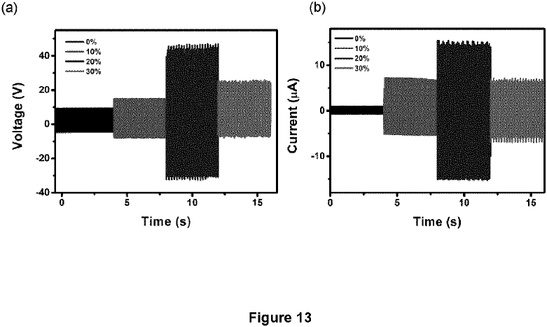

The pore size (and thus porosity) in the present perovskite-polymer film increases with the concentration of FAPbBr₂I precursors, which may play a key role in the PNG performance. It was found that the output voltage and current increases with the composition of FAPbBr₂I (up to ~ 85 V and ~ 30 µA at 20 wt. %) and decreases afterwards (FIG. 13). The PNG with 20 wt. % of FAPbBr₂I demonstrated the highest output performance, and after a certain threshold margin, the PNG performance started to degrade with the further addition of FAPbBr₂I NPs. While not wishing to be bound by any particular theory or mode of action, this may be attributed to one or a combination of the following factors: (i) PVDF per unit volume is greatly reduced due to the very high porosity; (ii) the film impedance is reduced by higher mass ratios (> 20 wt. %) of FAPbBr₂I which, as a result, causes the earlier dielectric breakdown before maximum polarization charges are achieved by electrical poling, and (iii) the defects generated by the agglomeration of FAPbBr₂I NPs.

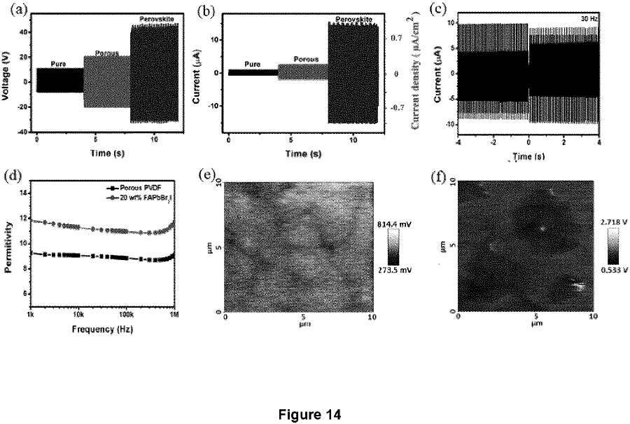

The highest measured output voltage and current of the PNG with 20 wt. % FAPbBr₂I was compared to the pure and 20 wt.% porous PVDF-based PNG devices (FIG. 13). The output voltage and current of the 20 wt. % perovskite-polymer PNGs were increased by ~ 5 times and ~ 15 times, respectively, compared to that of the pure PVDF-based PNG model (~ 17 V, and ~ 2 µA). Output voltage and current of the 20 wt. % perovskite-polymer PNGs were also substantially higher than that of the 20 % porous PVDF PNG (~ 40 V, ~ 6 µA). The generated electricity of the perovskite-polymer PNG originated from the inherent piezoelectric polarization⁸⁹⁻⁹⁵ was verified from the output polarity switching (FIG. 14) showing the expected output reversal.

Intrinsic material properties of the present perovskite-polymer film were also investigated. The relative permittivity of the porous PVDF film and perovskite-polymer film (20 wt. % FAPbBr₂I@PVDF) were measured in a frequency range of 1 kHz to 1 MHz (FIG. 14). For both films, at the lower frequency regime, permittivity was high at the beginning, likely due to the interfacial polarization effect between the nanoparticles and polymer interface,⁹⁶ which arises from the free carriers in the polymer material. However, with an increase in the applied electric field frequency, the interfacial polarization cannot cope with the frequency change, which resulted in the decreased permittivity. The increasing pattern of the relative permittivity was found to be correlated with the rising of a high frequency stray capacitance during the measurements. The higher permittivity of the perovskite-polymer film (~ 12 at 1 kHz) enhanced the piezoelectric performance, as it increased the piezoelectric coefficient (D₃). ⁹⁷⁻⁹⁹ In addition, the enhanced permittivity of FAPbBr₂I perovskites gave rise to the output current by reducing the internal impedance (Z) of the film:

$$Z = R - J \frac{d}{2 π A {ε}_{0} {ε}_{r}} \qquad \text{(3)}$$

where R. is the film resistance, d the thickness, A the area, ∈₀ the vacuum permittivity, and ∈ᵣ the relative permittivity.

The charges due to the internal polarization were also affected by the relative permittivity of FAPbBr₂I. The surface potential of the perovskite-polymer film was measured by employing Kelvin probe force microscopy (KPFM). The relationship between the permittivity and polarization can be expressed as 100:

$$\vec{P} = {ε}_{0} \left({ε}_{r} - 1\right) \vec{E} \qquad \text{(4)}$$

where P̅ is the electric polarization within the material, ε₀ the permittivity of free space (8.854× 10⁻¹²F m⁻¹), εᵣ the relative permittivity, and E̅ the electric-field.

From equation (4), the higher permittivity of the perovskite-polymer film due to the presence of perovskite will likely change the strain-induced electric field inside the film and, as a result, the magnitude of the surface potential will be different. In general, for perovskite-polymer PNGs, the surface potential is of particular interest because it affects band bending and carrier transport at the interfaces.¹⁰¹⁻¹⁰⁵ By measuring the contact potential difference using a platinum (Pt) KPFM tip (» 20 nm radius) in intermittent contact mode, the average surface potential of the perovskite-polymer film was found to be 1.1 V, which was more than twice that of porous PVDF film (FIG. 14). The observed variation in the average surface potential in the perovskite-polymer film was very small (<100 mV), which eliminates possible surface contamination by the remnant precursors-formamidinium iodide (FAI), or lead bromide (PbBr₂).

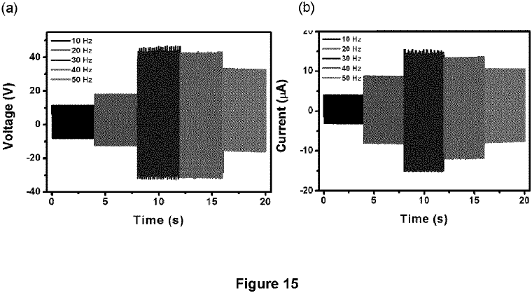

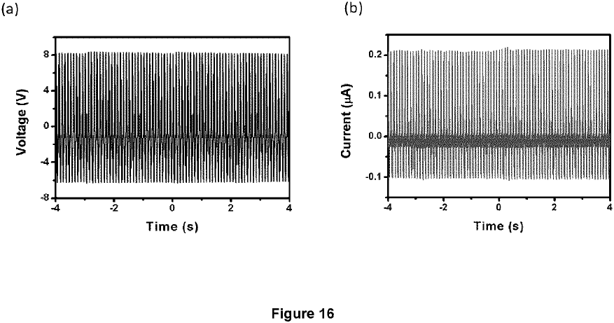

The ambient vibration-dependent output voltage and current of the perovskite-polymer PNG (FIG. 15) were also measured. By keeping the force constant, the frequency of the electrodynamic shaker was varied from 10-50 Hz by a controller unit (Vibration Research’s VR 9500 Revolution). Maximum output was obtained at 30 Hz, corresponding to the resonant condition in which the electromechanical coupling is the greatest. To evaluate the flexibility of the perovskite-polymer PNG, a periodic bending force was applied at a constant strain rate (15.5 cm/s) and the output voltage and current were measured. The peak to peak output voltage was 14 V and the current was 0.3 µA (FIG. 16), which could be enhanced further by increasing the bending radius.⁷⁴

### 3. Applications of PNGs as a Sustainable Power Source in IoT

A P-PNG comprising the present perovskite-polymer film was employed as a power source, to implement a self-powered integrated wireless electronics node (SIWEN) for the distributed network of IoT. This SIWEN was configured to remotely communicate with Bluetooth™-compatible personal electronics to transfer data from one or more distributed sensors.

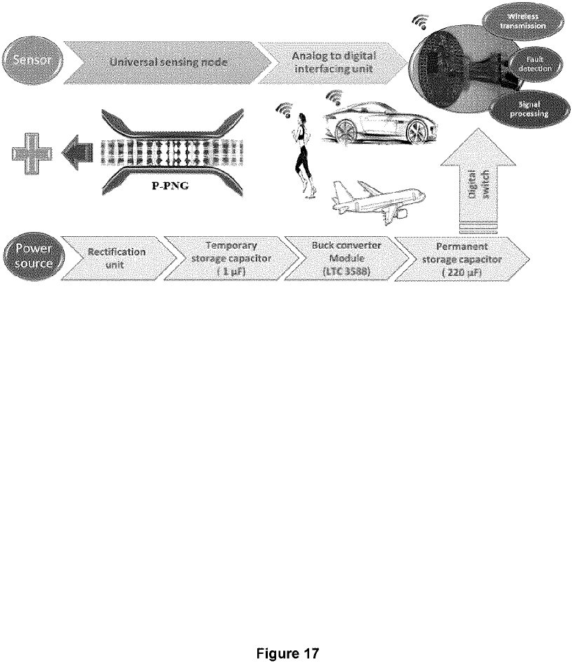

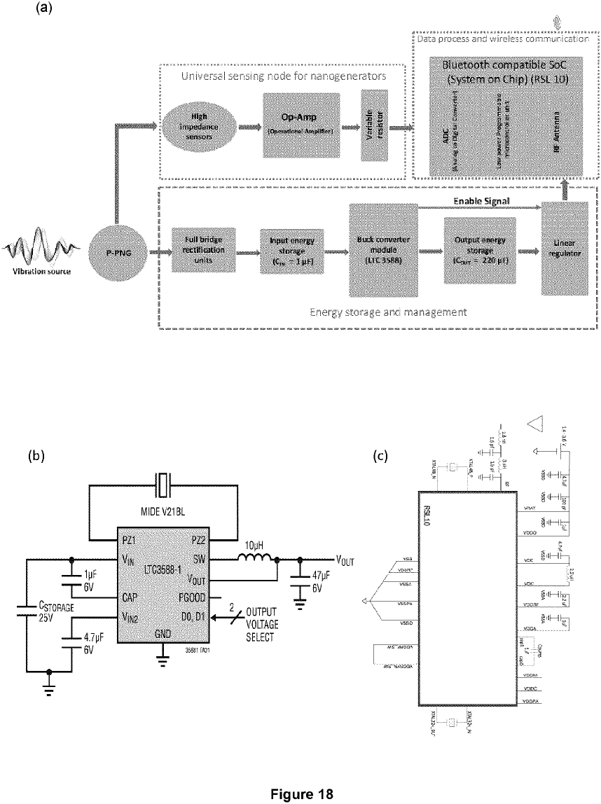

A functional block diagram of the SIWEN is illustrated in FIG. 17. The SIWEN incorporated a rectification unit, two-stage energy transfer system, regulated switches, and a low power system on chip (SoC) for conditioning sensor signal and transmitting it to a remote end receiver (FIG. 18). Before integrating the perovskite-polymer PNG with the SIWEN, practical load driving capability was confirmed. The maximum instantaneous power delivered to the load was measured from output currents with a wide range of external load resistances (100 KΩ to 80 MΩ) and a peak output power of ~ 105 µW was obtained, at a load resistance of 7 MS2.

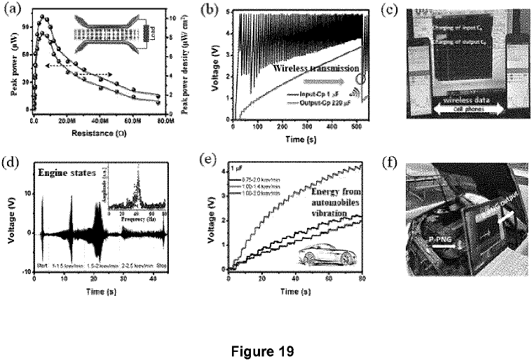

The perovskite-polymer PNG scavenged mechanical energy from tiny vibrations of an electrodynamic shaker (running at 30 Hz), storing the energy and powering up SIWEN to initiate data transfer. The measured charging characteristics of two-stage energy transfer system (enabled by two capacitors (Cp)) are illustrated in FIG. 19. When the voltage of an input capacitor (1 µF) reached ~ 5 V, which was regulated by a Zener diode, it discharged energy through a buck converter module to an output capacitor (220 µF). The Buck converter module consisted of two metal oxide semiconductor field-effect transistor (MOSFET) switches. After the output voltage of the 1 µF input capacitor dropped down to a regulated voltage of ~ 2-3 V, the 220 µF output capacitor was disconnected from it by the MOSFET switches and the input capacitor stopped discharging and started to be charged. In this manner, the output capacitor was charged until ~ 3.1 V with high energy transfer efficiency, and could empower the universal electronics node. The electrical energy stored in the 220 µF output capacitor was used to drive the Bluetooth™-compatible system on chip (SoC). Another perovskite-polymer PNG was incorporated in the system as a sensing unit, which was connected with an analog to digital converter (ADC) of the SoC via an impedance matching bridge. Immediately after reaching the output voltage of the 220 µF capacitor to 3.1 V, a trigger signal was sent to turn on a switch, through which the output capacitor discharged energy to power the SoC and transmitted the digital data to a remote receiver. The full operation of energy harvesting, energy-storing, data collecting, and wireless transmitting were demonstrated and recorded. As shown in FIG. 19, two smartphones were receiving the transmitted data from the SIWEN and decoding the mimic sensor (another perovskite-polymer PNG) signals.

The perovskite-polymer PNG was also used in harnessing vibration from an automobile vehicle. FIG. 19 illustrates the measured output voltage from the perovskite-polymer PNG when mounted on a car (while the engine is running), where device output reflected the acceleration and rotational speed-dependent vibration pattern of the engine. After the engine was turned on, the revolutions per minute (rpm) was varied from a range of 1-1.5, 1.5-2, 2-2.5 kilo revolutions per minute (krev/min) while maintaining a constant acceleration between each rpm regime. Initially, a peak-to-peak voltage of ~ 13 V was measured, which was likely attributed to the abrupt engine vibration upon initiation. Later, the perovskite-polymer PNG output dropped, due to a gradual decrease in the vibration magnitude in the higher rpm regimes. A fast Fourier transform was performed and revealed a major contribution of the device output produced from the vibration components of approximately 40 Hz, which was close to the resonance frequency of the perovskite-polymer PNG. By harnessing energy from such minute engine vibrations, a commercial capacitor of 1 µF was charged up to 4 V in ~ 1 minute. As illustrated in FIG. 19, the capacitor was continuously charged by switching the car rpm back and forth between 1-1.4 krev/min (red curve), 1-2 krev/min (blue curve), and 0.75-2 krev/min (black curve). The top charging performance at 1-1.4 krev/min is likely attributed to the highest acceleration and more frequent excitation (due to lower rpm switching time) to the capacitor. For the other two wider rpm regimes, acceleration was lower and the longer rpm switching time allowed the capacitor to further discharge its energy.

### B. Porous Pvdf Film

### 4. Experimental Methodologies

### 4.1 Fabrication of Porous PVDF Film

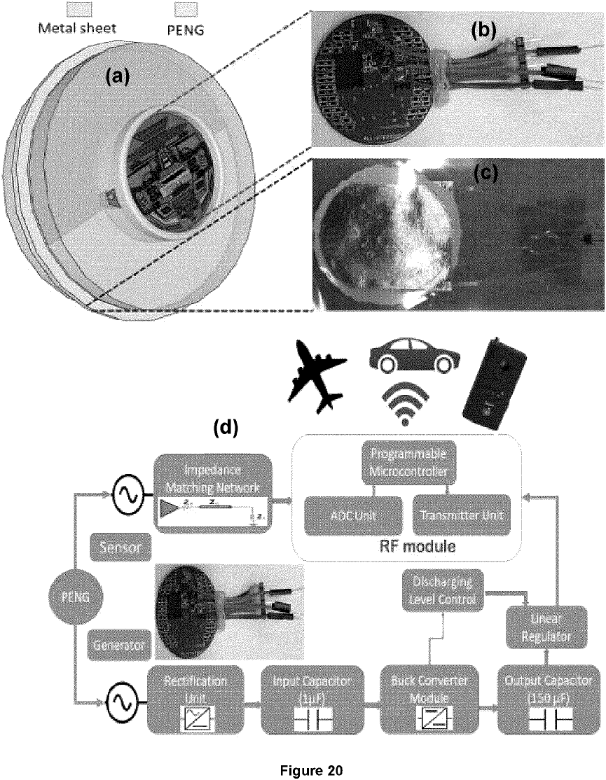

FIG. 20 illustrates another embodiment of the present composite film, in which the substrate comprises a polymer and the piezoelectric nanoparticles comprise ZnO. This porous PVDF film is then incorporated into the illustrated PNG. To prepare the porous PVDF film, PVDF powder (Sigma Aldrich) was dissolved in N, N-dimethylformamide (DMF) solvent (10 wt. %) at 70° C. for 24 hours and then ZnO NPs (35-45 nm, US Research Nanomaterials, Inc.) were mixed within the PVDF matrix solution and the mass ratio between ZnO NPs to PVDF was adjusted to create different porosity. The solution was stirred for another 4 hours on a hot plate at a temperature of 45° C. followed by extended ultra-sonication for 30 min to maximize the uniform distribution of ZnO-NPs within the PVDF polymer matrix. The suspension was then drop cast onto a circular shape Si wafer and degassing was performed at 65° C. in the vacuum oven with N₂ supplied to diminish the bubble formation during drop cast for 30 minutes. Next, the annealing was done in the same vacuum oven at a slightly increasing temperature (75° C.) for another 45 minutes. The film was then peeled from substrate and immersed in a 37 wt. % HCl solution for 4 hours to remove the ZnO NP from the PVDF matrix. After HCl etching, the films were washed by deionized (DI) water drying with N₂ air and put in the vacuum oven overnight at 60° C. for better drying.

### 4.2 Porous PVDF Film PNG Fabrication

A high voltage electrical poling of the present porous PVDF film was performed with an electric field of 70-120 Vµm⁻¹ for 5-6 hours with a DC voltage of 0-6 kV. The samples were stable throughout the poling process. No short circuit or noticeable voltage fluctuation was detected up to the maximum voltage of 6 kV. Then the poled porous PVDF film was inserted between two copper electrodes. For characterization purpose, the electrical connections were made from both of the top and bottom electrodes by very thin and flexible copper conductors. Finally, the layered structure of polyester/copper/porous PVDF film/copper/polyester was inserted and pass through a commercial thermal laminator to eliminate any air gaps.

### 4.3 Characterization and Measurements

JSM-7200F Field-emission scanning electron microscopy tools were used to characterize the morphology and structural properties of the present porous PVDF film. Fourier transform infrared spectroscopy (FTIR) was performed by Nicolet iS50 to confirm the piezoelectric β- phase formation inside the porous PVDF film by measuring characteristic absorbance peak between wavenumber ranges from 400 to 1000 cm⁻¹. Atomic force microscopy (AFM) image was captured by using JPK Nanowizard II, configured in intermittent-contact mode (scan rate 0.3 Hz). To investigate the electrical output performance of the porous PVDF PNG, an electrodynamic shaker (Lab works Inc.) was used, which was controlled by a power amplifier and a controller unit. To record electrical output from the PNG, a digital oscilloscope (Tektronix 2004 C) and a low-noise current preamplifier (Model- SR 570, Stanford Research System Inc.) were used.

### 5. Results and Discussion

A self-powered wireless structural health monitoring system can be a combination of an energy generation part, an energy management circuit, and a data transmission unit (RF module). In the system illustrated in FIG. 20, a PNG was placed between two metal sheets, to reflect the scenario of a PNG operating inside a mechanical j oint. The device was composed of the present porous PVDF film (~ 50 µm), which was sandwiched between two copper electrodes and encapsulated with polyester substrates. For the wiring purpose, very thin and flexible copper wires (~ 100 µm) were used from both of the top and bottom electrodes. Finally, the layered structure of polyester/copper/porous PVDF film/copper/polyester was compressed by a commercial thermal laminator to eliminate any air gaps by confirming uniform adhesion between each layer. As illustrated in FIG. 20, the custom-made wireless circuit was placed inside a groove of the metal sheets (as illustrated in FIG. 20), which in turn allowed energy management, storage, signal conditioning, and data transmission. The fabricated porous PVDF PNG device with proper packaging and electrodes connection for measuring purpose is illustrated in FIG. 20. In FIG. 20, the operation of the custom-designed wireless sensing node is described. Herein, the electrical output from the porous PVDF PNG was used for sensing and for powering up the data transmission unit. The alternating electrical output collected from the porous PVDF PNG was first rectified by a bridge rectifier unit and fed to the energy management module (EMM) to regulate and store the harvested energy in the input capacitor (1 µF) (temporary storage). Once the input capacitor was fully charged, and reached ~ 5 V, which was regulated by a Zener diode, it discharged energy through a buck converter module to an output capacitor (220 µF) and dropped down to a regulated voltage of ~ 2-3 V. The output capacitor (220 µF) was then disconnected from it by the MOSFET switches of the buck converter and the input capacitor started to charge up again to the regulated level of ~ 5 V and continued the charging-discharging cycle. The charging and discharging cycle of the input capacitor continued until the output capacitor was charged up to ~ 3.1 V, and by then, it empowered the whole data transmission system.

For the sensing purpose, the alternating output from the PNG was fed to the RF module via an impedance matching network (IMU), which contained a diode and an operational amplifier (Op-Amp) as shown in FIG. 20. The RSL-10 system on chip (SoC) of the RF module was programmed to operate for a pre-set ~ 1 second/data transmission cycle, during which the measured sensor signal from the PNG was digitized and transmitted wirelessly to the remote receivers (mobile phones). A discharging level controller of output capacitor based on a delay circuit was introduced to control the data transmission frequency. The whole system including the rectifier, EMM, the RF module, and the impedance matching unit were integrated on a circular printed circuit board (PCB) of a diameter of 3 cm as shown in FIG. 20. The full operation of energy harvesting, energy-storing, data collecting, and wireless transmitting were systematically demonstrated and recorded. The system was tested and its operation verified under different vibrating conditions of a linear electrodynamic shaker.

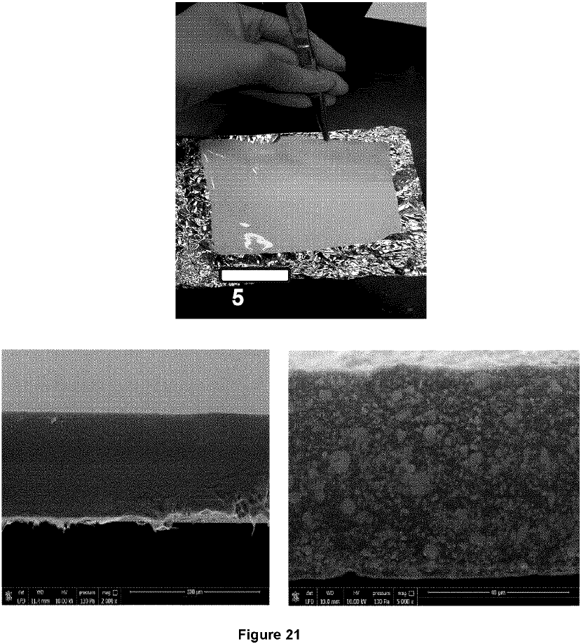

To exhibit the capability of fabricating high quality porous piezoelectric polymer film in mass scale, a large area porous PVDF film (approximately 15 cm × 15 cm) was fabricated using the above described method (FIG. 21).

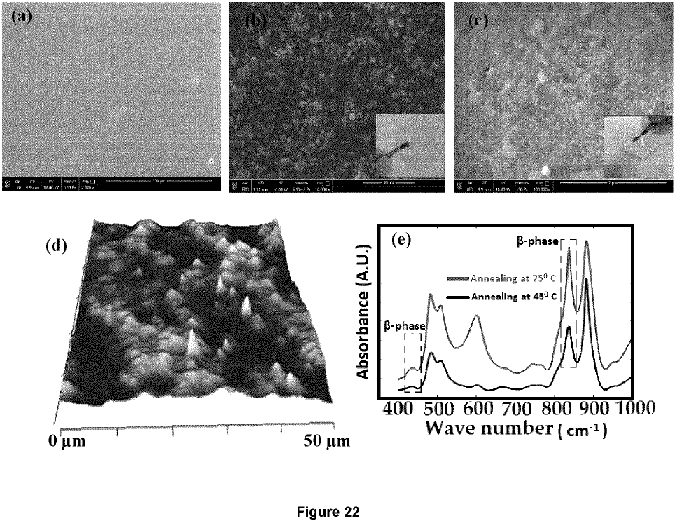

FIG. 22 illustrates the top surface Scanning Electron Microscopy (SEM) images of a pure PVDF film, indicating surface topography and composition of the sample, which was homogenous without wrinkles, grains, voids, cracks, or deformation. Whereas FIG. 22 illustrates the top surface SEM image of evenly distributed ZnO-NPs in the present porous PVDF film matrix (inset is the complete PVDF/ZnO NP-based PNG film). The purpose of introducing ZnO-NPs to the PVDF matrix is to create porosity (by HCl etching) in the PVDF film for enhancing its mechanical property as well as to enhance the development of the piezoelectric β-phase by the dipolar interaction between Zn²⁺ cation and CF2⁻ group of PVDF. Furthermore, ZnO has several unique advantages compared to inorganic (e.g., SiO₂,) or organic (e.g., polystyrene) NPs for the fabrication of porous nanostructures, including cost-effective, non-toxicity, good scalability, and facile removal by acidic solution. From FIG. 22, it can be seen that the ZnO NPs were distributed randomly, and accumulated inside the PVDF film like a cluster, which was likely due to their molecular weight (ZnO NPs are heavier than PVDF molecule). FIG. 21 (b-c) illustrates the cross-section SEM images of pure PVDF and distributed ZnO-NPs in the PVDF matrix, respectively.

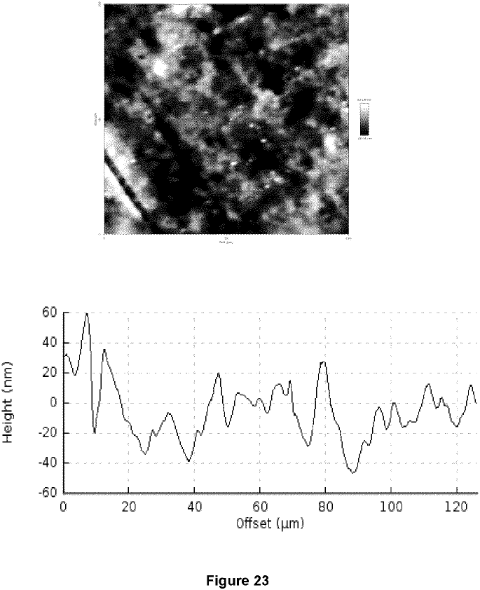

After the etching process, the surface of the PVDF became quite rough (FIG. 23 (a-b)). Scanning electron microscopy (SEM) images shown in FIG. 22 illustrates the top surface of the present porous PVDF film after removing ZnO-NPs followed by the HCl etching and the inset illustrates the porous PVDF film after HCl etching. During the etching process, hydrochloric acid (HCl) reacted first with the inorganic ZnO nanoparticles in the surface, and then gradually entered the PVDF film. As ZnO NPs were distributed randomly throughout the film, pores were not only formed on the surface but throughout the whole film and the size of the pores were larger than the actual nanoparticle size. The atomic Force Microscopy (AFM) image in FIG. 22 is a 3-dimensional surface topology image of the porous PVDF film. As seen in FIG. 22, the surface roughness of the porous PVDF film is approximate ~ 100 nm (FIG. 23).

In addition to porosity, achieving β-phase crystallinity of PVDF is desirable, as it has been reported to posses the highest spontaneous polarization than the other polymorphic phases of the PVDF (α, γ, δ). To confirm the β-phase formation of present porous PVDF film, Fourier Transform Infrared (FTIR) spectrum analysis in the wavenumber range of 400-1000 cm⁻¹ was performed. The characteristic peaks of the β-phase at 431 and 840 cm⁻¹ can be observed in the FTIR spectrum in FIG. 22. While not wishing to be bound by any particular theory or mode of action, the formation of β-phase in the PVDF matrix may be attributed, at least in part, to the interactions between the dipoles of PVDF and surface charges on ZnO-NPs. The positively charged Zn cations (0001 surfaces) and O-terminated anions (0001 surfaces) interact with the PVDF CF₂⁻ or CH₂⁺ groups that have negative and positive charge densities, respectively, and results in the β-phase nucleation. Upon applying a high electric poling field, the dipoles of PVDF align in the direction of the field.

In the SHM system, the oscillation and mechanical vibration from the electrodynamic shaker was transported across the surface and pressed accordingly to the porous PVDF PNG located between the shaker hammer and a block of stainless steel, which produced piezoelectric output. The PNG-weight system can be demonstrated as a spring-mass system similar to a free vibration system with damping.

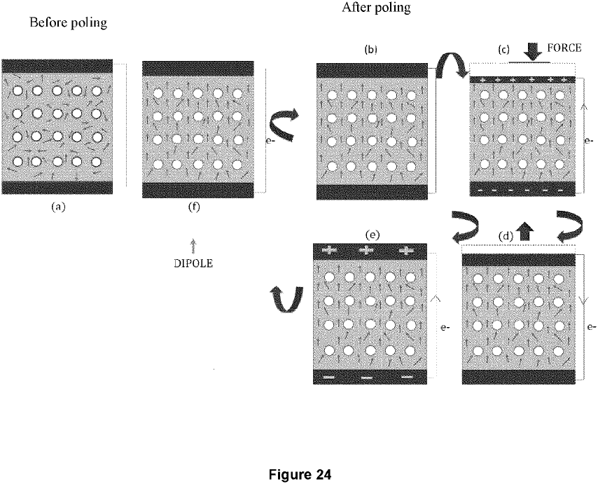

While not wishing to be bound by any particular theory or mode of action, FIG. 24 illustrates a schematic representation of the electricity generation mechanisms from the poled porous PVDF PNG. In the beginning, the net dipole moment inside the porous PVDF film is zero with the absence of externally applied force. When a vertical compressive force is applied on the device, the net polarization within the PNG changes and thus resulting in a piezoelectric potential. This will force the free electrons to move from one electrode to the other. After releasing the force, the piezoelectric potential will be diminished and electrons will move back.

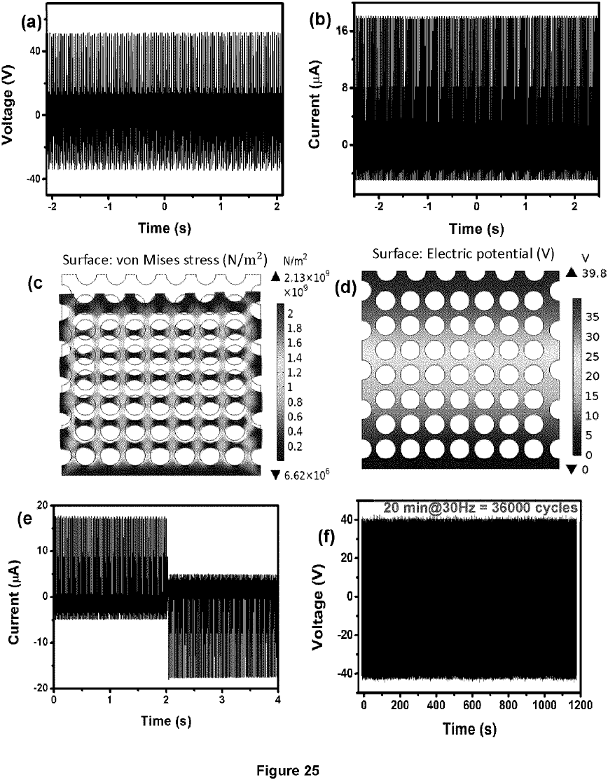

As shown in FIG. 25, the measured peak-to-peak output open-circuit voltage (Voc) and Short circuit current (Isc) at 30 Hz frequency was about 84.5 V and 22 µA, respectively from an active device area of 11.3 cm² for a 50 wt. % ZnO@PVDF device. This porous PVDF PNG showed an increase in the output current and voltage performance of ~ 11 times (~ 22 µA p-p), and ~ 8 times (~ 84.5 V p-p), respectively compared to pure PVDF. While not wishing to be bound by any particular theory or mode of action, the pores inside the PVDF may influence the stress distribution inside the film, and boost the strain-induced piezo potential.

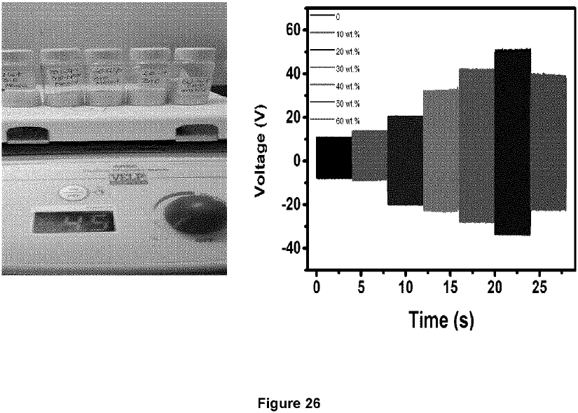

As porosity is an important factor controlling the mechanical energy harvesting capability, the effect on practical PNG device performance were also examined. PVDF thin films of different porosities were prepared from the mixture of ZnO NPs of different mass ratios (wt. %) (FIG. 26). When the ZnO mass fraction increased from 0 wt. %(pure PVDF) to 50 wt. %, the enhancement in the porosity percentages further boosted the PNG output voltage from 18 V(p-p) to 84.5 V(p-p), measured at a frequency of 30 Hz. However, a further increase in the ZnO mass ratios (60 wt. %) decreased the output voltage to 60 V(p-p) (FIG. 26). The PNG film made from the mixture of 50 wt.% of ZnO showed the highest output performance.

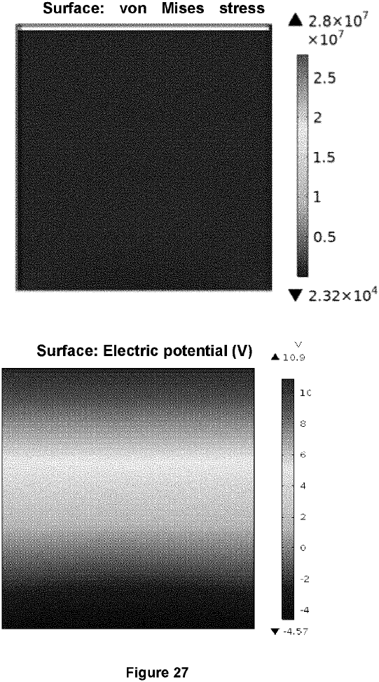

To validate the experimental result, a PNG model based on the finite element simulations was developed (COMSOL Multiphysics 5.3). The model was then compared with the pure PVDF film and the 50 wt. % of porous PVDF film. FIG. 25 illustrates the stress distribution and output voltage of the porous PVDF film under uniaxial compressive stress of 800 kPa, whereas the FIG. 27 illustrates the result for pure PVDF film. The induced displacement and output of the two PNG models having same film thickness was different, with the porous PVDF film experiencing a larger deformation than the pure PVDF and therefore a larger output voltage. While not wishing to be bound by any particular theory or mode of action, this phenomenon may, at least in part, be attributed to the position of pores and size influence stress distribution on the PVDF film.

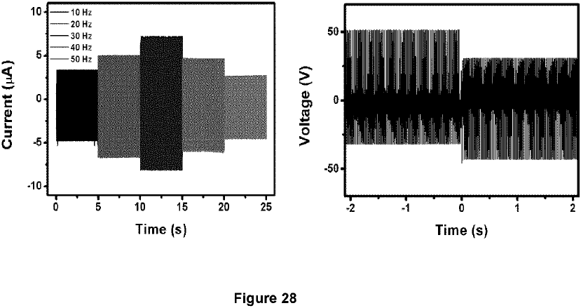

As a general validation to confirm the inherent piezoelectricity originated from the porous PVDF PNG, a polarity-switching test was carried out. When the connection was reversed, the reversal in the open-circuit voltage (FIG. 28) and the short circuit current (FIG. 25) revealed identical amplitude with reversed polarization, which confirmed the authenticity of the piezoelectric output signals. The PNG’s output was sustained under a constant oscillation without a notable degradation in the output signal for 36000 cycles (30 Hz for 20 minutes) (FIG. 25).

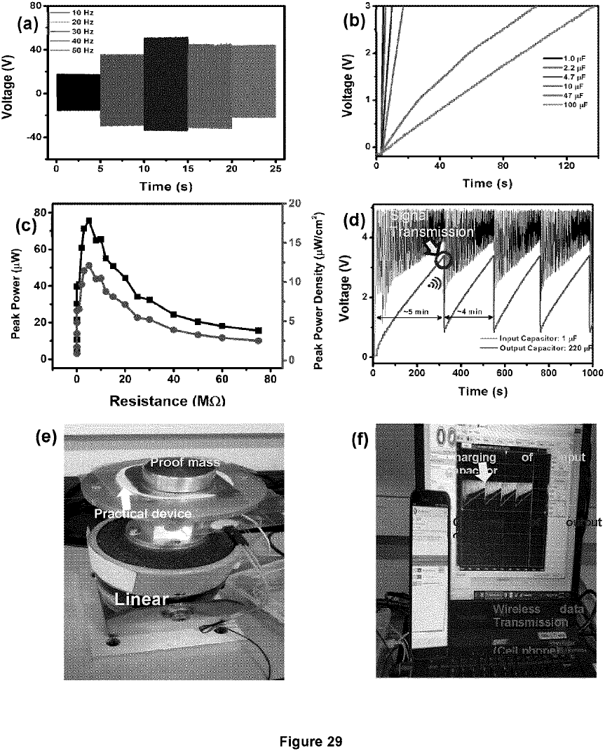

To verify the suitability of the porous PVDF PNG-based SHM system, broadband energy harvesting capability of the open-circuit voltage (FIG. 29) and short circuit current (FIG. 28) of the porous PVDF PNG was measured within a frequency range from 10 Hz to 50 Hz (varied the frequency of electrodynamic shaker by a Vibration Research’s VR9500 controller unit). The piezoelectric output increased up to 30 Hz and the maximum VOC was recorded at this point, which corresponded to the resonant condition of the system and was due to the necessary input power increase of the oscillator. The harnessed energy was stored in different valued commercial capacitors through a full-wave bridge circuit. FIG. 29 illustrates the charging characteristics of up to 3 V of 1.0 µF, 2.2 µF, 4.7 µF, 10 µF, 47 µF and 100 µF capacitors, where it took 140 seconds for 100 µF capacitor. It has been reported that the higher/faster energy storage in the input capacitor of a two-stage charging system enhances the energy transfer efficiency to the output capacitor as well as reduces its charging time.⁴⁶ Subsequently, based on the output-rectified currents measured from a wide range of external load resistances, the maximum instantaneous power delivered to the load was investigated. The peak output power (P=I²R) 78 µW and the corresponding peak power density of 12 µW/cm² were achieved at a load resistance of 7 MΩ as presented in FIG. 29, (whereas the no-load peak power and peak power density were .46 mW and 41.02 µW/cm², respectively), which was sufficient for driving the wireless SHM system. As shown in FIG. 29, the porous PVDF PNG produced electrical energy from the vibration of an electrodynamic shaker running at 30 Hz, and charged the input capacitor (1 µF) with the rectified output. When the charging voltage of the input capacitor reached ~ 5 V, which was regulated by a Zener diode, it discharged energy through a buck converter module to an output storage capacitor (220 µF). Buck converter module was enabled by two MOSFET switches. After the output voltage of the 1 µF capacitor dropped down to a regulated voltage of ~2-3 V, 220 µF capacitor was disconnected from it by the MOS switches and the input capacitor again started charging. In this manner, the output capacitor was charged until ~ 3.1 V with high energy transfer efficiency, and could power the universal electronics node. The voltage in this particular example drove a Bluetooth™-compatible System on Chip (SoC). As a sensing unit, another porous PVDF PNG device was incorporated, which was connected with the analog to digital converter (ADC) of SoC via an impedance matching bridge. Immediately after reaching the output voltage of 220 µF capacitor to 3.1 V, a digital signal was enabled to turn on a switch, through which the output capacitor discharged energy to trigger SoC and transmitted ADC sampled data points of the sensor to a remote receiver. FIG. 29 illustrates the setup, where the device was mounted on top of a linear mechanical shaker and weighted by a standard mass of 130 gram. FIG. 29 illustrates a Bluetooth™ receiver of a smartphone receiving and decoding the mimic sensor signals simultaneously.

While this invention has been described with reference to illustrative embodiments and examples, the description is not intended to be construed in a limiting sense. Thus, various modifications of the illustrative embodiments, as well as other embodiments of the invention, will be apparent to persons skilled in the art upon reference to this description. It is therefore contemplated that the appended claims will cover any such modifications or embodiments.

All publications, patents and patent applications referred to herein are incorporated by reference in their entirety to the same extent as if each individual publication, patent, or patent application was specifically and individually indicated to be incorporated by reference in its entirety.

### LIST OF REFERENCES CITED

1. C. Soci, A. Zhang, B. Xiang, S. A. Dayeh, D. Aplin, J. Park, X. Bao, Y.-H. Lo and D. Wang, Nano Lett., 2007, 7, 1003.

2. Y. Qi and M. C. Mcalpine, Energy Environ. Sci., 2010, 3, 1275.

3. R. S. Yang, Y. Qin, L. M. Dai and Z. L. Wang, Nat. Nanotechnol., 2009, 4, 34.

4. M. Y. Choi, D. Choi, M. J. Jin, I. Kim, S. H. Kim, J. Y. Choi, S. Y. Lee, J. M. Kim and S. W. Kim, Adv. Mater., 2009, 21, 2185.

5. T. Xu, X. Ding, Y. Huang, C. Shao, L. Song, X. Gao, Z. Zhang and L. Qu, Energy Environ. Sci., 2019, 12, 972.

6. Y. F. Hu, Y. Zhang, C. Xu, L. Lin, R. L. Snyder and Z. L. Wang, Nano Lett., 2011, 11, 2572.

7. C. L. Sun, J. Shi, D. J. Bayerl and X. D. Wang, Energy Environ. Sci., 2011, 4, 4508.

8. G.-T. Hwang, H. Park, J.-H. Lee, S. Oh, K.-I. Park, M. Byun, H. Park, G. Ahn, C. K. Jeong, K. No, H. Kwon, S.-G. Lee, B. Joung and K. Jae, Adv. Mater., 2014, 26, 4880.

9. X. Qing, W. Li, Y. Wang and H. Sun, Sensors, 2019, 19, 545.

10. M. H. F. Alibadi, Z. S. Khodaei, World Scientific Publishing Europe Ltd. London, UK, 2018.

11. W. Staszewski, S. Mahzan, and R. Traynor, Compos. Sci. Technol. 2009, 69, 1678.

12. L. Qiu, S. Yuan, C. Boller, Struct. Health Monit. 2017, 16, 501.

13. M. Q. Le, J. F. Capsal, M. Lallart, Y. Hebrard, A.V. D. Ham, N. Reffe, L. Geynet, and P. J. Cottinet, Prog. Aerosp. Sci., 2015, 79, 147.

14. S. Wang, Z. L. Wang and Y. Yang, Adv. Mater., 2016, 28, 2881.

15. S. Jang, H. Kim, Y. Kim, B. J. Kang and J. H. Oh, Appl. Phys. Lett., 2016, 108, 143901.

16. C. Kumar, A. Gaur, S. Tiwari, A. Biswas, S. K. Rai and P. Maiti, Composites Communications, 2019, 11, 56.

17. S. S. Won, M. Sheldon, N. Mostovych, J. Kwak, B. S. Chang, C. W. Ahn, A. I. Kingon, I. W. Kim and S. H. Kim, Appl. Phys. Lett., 2015, 107, 202901.

18. S. J. Park, S. H. Lee, M. L. Seol, S. B. Jeon, H. Bae, D. Kim, G. H. Cho, Y. K. Choi, Nano Energy, 2019, 55, 115.

19. T. X. Xiao, X. Liang, T. Jiang, L. Xu, J. J. Shao, J. H. Nie, Y. Bai, W. Zhong, Z. L. Wang, Adv. Funct. Mater., 2018, 28, 1802634.

20. I. Sari, T. Balkan, H. Kulah, Sens. Actuators A Phys., 2018, 145, 405.

21. C.R. Saha, T.O′Donnell, N. Wang, P. McCloskey, Sens. Actuators A Phys., 2008, 147, 248.

22. S.P. Beeby, R.N. Torah, M.J. Tudor, P. Glynne-Jones, T. O′Donnell, C.R. Saha, S. Roy, J. Micromech. Microeng., 2007, 17 1257.

23. P.D. Mitcheson, P. Miao, B.H. Stark, E.M. Yeatman, A.S. Holmes, T.C. Green, Sens. Actuators A Phys., 2004, 115, 523.

24. H. Tian, S. Ma, H. M. Zhao, C. Wu, J. Ge, D. Xie, Y. Yang, T. L. Ren, Nanoscale, 2013, 5, 8951.

25. Z.L. Wang, J. Song, Science., 2006, 312, 242.

26. F.R. Fan, Z.Q. Tian, Z. L. Wang, Nano Energy, 2012, 1, 328.

27. W. Liu, Z. Wang, G. Wang, G. Liu, J. Chen, X. Pu, Y. Xi, X. Wang, H. Guo, C. Hu, Z. L. Wang, Nat. Commun., 2019,10, 1426.

28. A.A. Khan, A. Mahmud, S. Zhang, S. Islam, P. Voss, D. Ban, Nano Energy, 2019, 62, 691.

29. Z. L. Wang, T. Jiang, L. Xu, Nano Energy, 2017, 39, 9.

30. J. Nie, Z. Ren, J. Shao, C. Deng, L. Xu, X. Chen, M. Li, Z. L. Wang, ACS Nano, 2018, 12, 491.

31. Y. Bai, C. B. Han, C. He, G. Q. Gu, J. H. Nie, J. J. Shao, T. X. Xiao, C. R. Deng, Z. L. Wang, Adv. Funct. Mater., 2018, 28, 1706680.

32. X. Cao, M. Zhang, J. Huang, T. Jiang, J. Zou, N. Wang, Z. L. Wang, Adv. Mater., 2018, 30, 1704077.

33. D. H. Kim, H. J. Shin, H. Lee, C. K. Jeong, H. Park, G. T. Hwang, H. Y. Lee, D. J. Joe, J. H. Han, S. H. Lee, J. Kim, B. Joung, K. J. Lee, Adv. Funct. Mater., 2017, 27, 1700341.

34. H. S. Wang, C. K. Jeong, M. H. Seo, D. J. Joe, J. H. Han, J. B. Yoon, K. J. Lee, Nano Energy, 2017, 35, 415.

35. S. Li, J. Wang, W. PNG, L. Lin, Y. Zi, S. Wang, G. Zhang, Z. L. Wang, Adv. Energy Mater., 2017, 7, 1602832.

36. J. Chen, H. Guo, X. He, G. Liu, Y. Xi, H. Shi, C. Hu, ACS Appl. Mater. Interfaces, 2016, 8, 736.

37. A. A. Khan, A. Mahmud, D. Ban, IEEE Transactions on Nanotechnology, 2018, 18, 21.

38. J. Chen, Y. Huang, N. Zhang, H. Zou, R. Liu, C. Tao, X. Fan and Z. L. Wang, Nat. Energy, 2016, 1, 16138.

39. X. Guan, B. Xu, J. Gong, Nano Energy, 2020, 70, 104516.

40. V. Jella, S. Ippili, J. Eom, J.H Choi, S.G. Yoon, Nano Energy, 2018, 53, 46.

41. R. Ding, X. Zhange, G. Chen, H. Wang, R. Kishor, J. Xiao, F. Gao, K. Zeng, X. Chen, X. W. Sun, Y. Zheng, Nano Energy, 2017, 37, 126.

42. C. Hu, L. Cheng, Z. Wang, Y. Zheng, S. Bai and Y. Qin, Small, 2016, 12, 1315.

43. Y. Hu, C. Xu, Y. Zhang, L. Lin, R.L. Snyder, Z.L. Wang, Adv. Mater., 2011, 23, 4068.

44. S. N Cha, S. M Kim, H. Kim, J.Ku, J. I. Sohn, Y. J. Park, B. G. Song, M. H. Jung, E. K. Lee, B. L. Choi, J. J. Park, Z. L. Wang, J. M. Kim, K. Kim, Nano Lett. 2011, 11, 5142.

45. S. Lu, Q. Liao, J. Qi, S Liu, Y Liu, G. Zhang, Y. Zhang, Nano Res. 2016, 9, 372.

46. J. Li, S. Chen, W. Liu, R. Fu, S. Tu, Y. Zhao, L. Dong, B. Yan, Y. Gu, J. Phys. Chem. C, 2019, 123, 11378.

47. Y. Su, K. Gupta, Y. Hsiao, R. Wang and C. Liu, Energy Environ. Sci., 2019, 12, 410.

48. Y. Mao, P. Zhao, G. McConohy, H. Yang, Y. Tong, X. Wang, Adv. Energy Mater., 2014, 4, 1301624.

49. G. Zhang, P. Zhao, X. Zhang, K. Han, T. Zhao, Y. Zhang, C. K. Jeong, S. Jiang, S. Zhang and Q. Wang, Energy Environ. Sci., 2018, 11, 2046.

50. C. R. Bowen, H. A. Kim, P. M. Weaver and S. Dunn, Energy Environ. Sci., 2014, 7, 25.

51. D. Chen, K. Chen, K. Brown, A. Hang, J. X. J. Zhang., Appl. Phys. Lett., 2017, 110, 153902.

52. Z. Zhang, C. Yao,Y. Yu, Z. Hong, M. Zhi, X. Wang, Adv. Funct. Mater, 2016, 26, 6760.

53. X. Yuan, X. Gao, J. Yang, X. Shen, Z. Li, S. You, Z. Wang and S. Dong, Energy Environ. Sci., 2020, 13, 152.

54. J.-H. Lee, K. Y. Lee, M. K. Gupta, T. Y. Kim, D.-Y. Lee, J. Oh, C. Ryu, W. J. Yoo, C.-Y. Kang, S. -Y. Yoon, J.-B. Yoo, S. -W. Kim, Adv. Mater., 2013, 26, 765.

55. J. Zhu, W. Song, F. Ma, H. Wang, Mater. Res. Bull., 2018, 102, 130.

56. K. Zhang, S. Wang and Y. Yang, Adv. Energy Mater., 2017, 7, 1601852.

57. C.-H. Wang, W.-S. Liao, Z.-H. Lin, N.-J. Ku, Y.-C. Li, Y.-C. Chen, Z. L. Wang, C.-P. Liu, Adv. Energy Mater., 2014, 4, 1400392.

58. X. Xue, Y. Nie, B. He, L. Xing, Y. Zhang, Z. L. Wang, Nanotechnology 2013, 24, 22.

59. Y. Fu, W. Zang, P. Wang, L. Xing, X. Xue, Y. Zhang, Nano Energy, 2014, 8, 34.

60. S. A. Han, T. -H. Kim, S. K. Kim, K. H. Lee, H. -J. Park, J. -H. Lee, S. -W. Kim, Adv. Mater., 2018, 30, 1800342.

61. A. Mahmud, A.A Khan, P. Voss, T. Das, E. Abdel-Rahman, D. Ban, Adv. Mater. Interfaces, 2018, 5, 1801167.

62. J.H. Jung, M. Lee, J. Hong, Y. Ding, C. Chen, L. Chou, Z.L. Wang, ACS Nano, 2011, 5,10041.

63. S. Xu, Y.-W. Yeh, G. Poirier, M. C. Mcalpine, R. A. Register,N. Yao, Nano Lett., 2013, 13, 2393.

64. G. Romano, G. Mantini, A. D. Carlo, A. D′Amico, C. Falconi, Z. L. Wang, Nanotechnology, 2011, 22, 465401.

65. K. I. Park, S. Xu, Y. Liu, G. T. Hwang, S. J. L. Kang, Z. L. Wang and K. J. Lee, Nano Lett., 2010, 10, 493.

66. C. K. Jeong, I. Kim, K. I. Park, M. H. Oh, H. Paik, G. T. Hwang, K. No, Y. S. Nam and K. J. Lee, ACS Nano, 2013, 7, 11016.

67. S. -H. Shin, Y. -H. Kim, M. H. Lee, J. -Y. Jung, J. H. Seol, J. Nah, ACS Nano, 2014, 8, 10844.

68. C. Baek, J. H. Yun, J. E. Wang, C. K. Jeong, K. J. Lee, K. I. Park and D. K. Kim, Nanoscale, 2016, 8, 17632.

69. K. I. Park, M. Lee, Y. Liu, S. Moon, G. T. Hwang, G. Zhu, J. E. Kim, S. O. Kim, D. K. Kim, Z. L. Wang and K. J. Lee, Adv. Mater., 2012, 24, 2999.

70. C. K. Jeong, K. I. Park, J. Ryu, G. T. Hwang and K. J. Lee, Adv. Funct. Mater., 2014, 24, 2620.

71. K. Shi, B. Sun, X. Huang, P. Jiang, Nano Energy, 2018, 52, 153.

72. S.K. Ghosh, A. Biswas, S. Sen, C. Das, K. Henkel, D. Schmeisser, D. Mandal, Nano Energy, 2016, 30, 30621.

73. Y.L. Zhao, Q.L. Liao, G.J. Zhang, Z. Zhang, Q.J. Liang, X.Q. Liao, Y. Zhang, Nano Energy, 2015, 11, 719.

74. B.S. Lee, J. Yoon, C. Jung, D.Y. Kim, S.Y. Jeon, K.H. Kim, J.H. Park, H. Park, K.H. Lee, Y.S. Kang, J.H. Park, H. Jung, W.R. Yu, S.G. Doo, ACS Nano, 2016, 10, 2617.

75. E. J. Lee, T. Y. Kim, S. Kim, S. Jeong, Y. Choi and S. Y. Lee, Energy Environ. Sci., 2018, 11, 1425.

76. A. Sultana, M. Alam, P. Sadhukhan, U.K.Ghorai, S. Das, T.R. Middya, D. Mandal, Nano Energy, 2018, 49, 380.

77. R. Ding, H. Liu, X. Zhang, J. Xiao, R. Kishor, H. Sun, B. Zhu, G. Chen, F. Gao, X. Feng, J. Chen, X. Chen, X. Sun, Y. Zheng, Adv. Funct. Mater., 2016, 26, 7708.

78. S. K. Ghosh, T. K. Sinha, B. Mahanty, D. Mandal, Energy Technology, 2015, 3, 1190.

79. A. Sultana, P. Sadhukhan, M. M. Alam, S. Das, T. R. Middya, D. Mandal, ACS Applied Materials & Interfaces, 2018, 10, 4121.

80. S. K. Ghosh, T. K. Sinha, B. Mahanty, S. Jana, D. Mandal, J. Appl. Phys., 2016, 120, 174501.

81. W. Ma, J. Zhang, S. Chen, X. Wang, J. Macromol. Sci., 2008, 47, 434.

82. H.L.W. Chan, M.C. Cheung, C.L. Choy, Ferroelectrics, 1999, 224, 113.

83. Q. Zhou, Z. Bai, W. Lu, Y. Wang, B. Zou, H. Zhong, Adv. Mater., 2016, 28, 9163.

84. X. Li, M. Guo and S. Dong, IEEE Trans. Ultrason. Ferroelectr. Freq. Control, 2011, 58, 698.

85. H.-X. Zou, W.-M. Zhang, W.-B. Li, Q.-H. Gao, K.-X. Wei, Z.-K. PNG, G. Meng, Smart Materials and Structures, 2017, 2611.

86. X. Gao, J. Wu, Y. Yu, Z. Chu, H. Shi and S. Dong, Adv. Funct. Mater., 2018, 28, 1706895.

87. W. Yang, W. Gong, C. Hou.et al. Nat Commun., 2019, 10, 5541.

88. Q. Sun, W. Seung, B.J. Kim, S. Seo, S.-W. Kim, J.H. Cho, Adv. Mater.,2015, 27, 3411.

89. Z. L. Wang, J. Chen and L. Lin, Energy Environ. Sci., 2015, 8, 2250.

90. W. L. Wang,, K. J. Liao, C. G. Hu, S. X. Wang, C. Y. Kong and H. Y. Liao, Sensors and Actuators A: Physical, 2003, 108, 55.

91. T. Quan, Y. Yang, Nano Res., 2016, 9, 2226.

92. W. Seung, H.-J. Yoon,T.Y. Kim, H. Ryu, J. Kim, J. -H. Lee „ S. Kim, Y. K. Park, Y. J. Park, S. -W. Kim, Adv. Energy Mater. 2017, 7, 160098.

93. S. Qin, Q. Zhang, X. Yang, M. Liu, Q. Sun, Z. L. Wang, Adv. Energy Mater.,2018, 8, 1800069.

94. J. Luo, Z. Wang, L. Xu, A. Wang, K. Han, T. Jiang, Q. Lai, Y. Bai, W. Tang, F. R. Fan, Z. L. Wang, Nat Commun., 2019, 10, 5147.

95. S. Priya, J. Electroceram., 2007, 19, 167.

96. S. Luo, Y. Shen, S. Yu, Y. Wan, W. Liao, R. Sun and C. Wong, Energy Environ. Sci., 2017, 10, 137.

97. A. Jain, P. K. J., A. K. Sharma, A. Jain, R. P.N, Polym. Eng. Sci., 2015, 55, 158.

98. R. Fries, A.J. Moulson, J. Mater. Sci.: Mater. Electron., 1994, 5, 238.

99. T. Zheng, H. Wu, Y. Yuan, X. Lv, Q. Li, T. Men, C. Zhao, D. Xiao, J. Wu, K. Wang, J. Li, Y. Gu, J. Zhu and S. J. Pennycook, Energy Environ. Sci., 2017, 10, 52.

100. S. Sadewasser, T. Glatzel, S. Schuler, S. Nishiwaki, R. Kaigawa and M. C. Lux-Steiner, Thin Solid Films, 2003, 257, 431.

101. H. Röhm, T. Leonhard, M. J. Hoffmann and A. Colsmann, Energy Environ. Sci., 2017, 10, 950.

102. A. D. Schulz, H. Röhm, T. Leonhard, S. Wagner, M. J. Hoffmann, A. Colsmann, Nat. Mater., 2019, 18, 1050.

103. A. H. Rahmati, S. Yang, S. Bauer and P. Sharma, Soft Matter, 2019, 15, 127.

104. A. Kuchler, High Voltage Engineering: Fundamentals-Technology-Applications, Springer Vieweg, Berlin, Germany 2018, 79.

105. K. Wang, Y. Hou, B. Poudel, D. Yang, Y. Jiang, M.-G. Kang, K. Wang, C. Wu, S. Priya, Adv. Energy Mater., 2019, 9, 1901753.

106. K. I. Park, C. K. Jeong, J. Ryu, G. T. Hwang and K. J. Lee, Adv. Energy Mater., 3 (12) 2013, 1539-1544.

107. J. Yan and Y. G. Jeong,, ACS Appl. Mater. Interfaces, 8 (24) (2016) 15700-15709.

108. J. M. Wu, C. Xu, Y. Zhang, and Z. L. Wang, 6 (5) (2012) 4335-4340.

109. C. Kumar, A. Gaur, S. K. Rai and P. Maiti,, Nano-Struct. Nano-Objects, 12 (2017) 174-181.

110. A. Gaur, R. Shukla, B. Kumar, A. Pal, S. Chatterji, R. Ranjan and P. Maiti,, Polymer, 97 (2016) 362-369.

111. R. A. Whiter, V. Narayan and S. K. Narayan, Adv. Energy Mater., 4 (18) (2014) 1400519.

112. S. Paria, S. K. Karan, R. Bera, A. K. Das, A. Maitra and B. B. Khatua, Ind. Eng. Chem. Res., 55 (40) (2016) 10671-10680.

113. A. Gaur, S. Tiwari, C. Kumar and P. Maiti, Nanoscale Advances, 1 (2019) 3200-3211.

114. S.K. Karan, R. Bera, S. Paria, A.K. Das, S. Maiti, A. Maitra, B.B. Khatua, Advanced Energy Materials 6 (2016) 1601016.

115. K. Shi, B. Sun, X. Huang, P. Jiang, Nano Energy 52 (2018) 153-162.

116. P. Thakur, A. Kool, N.A. Hoque, B. Bagchi, F. Khatun, P. Biswas, D. Brahma, S. Roy, S. Banerjee, S. Das, Nano Energy 44 (2018) 456-467.

117. X. Chou, J. Zhu, S. Qian, X. Niu, J. Qian, X. Hou, J. Mu, W. Geng, J. Cho, J. He, C. Xue, Nano Energy 53 (2018) 550-558.

118. S. Ye, C. Cheng, X. Chen, X. Chen, J. Shao, J. Zhang, H. Hu, H. Tian, X. Li, L. Ma, W. Jia, Nano Energy 60 (2019) 701-714.

119. H. Zhong, J. Xia, F. Wang, H. Chen, H. Wu, S. Lin, Adv. Funct. Mater., 27 (2017) 1604226.

120. X. Chen, H. Tian, X. Li, J. Shao, Y. Ding, N. An, Y. Zhou, Nanoscale 7 (2015) 11536-11544.

121. S. K. Ghosh, D. Mandal, Nano Energy, 53 (2018) 245-257.

122. M. O. G. Nayeem, S. Lee, H. Jin, N. Matsuhisa, H. Jinno, A. Miyamoto, T. Yokota, and T. Someya, PNAS, 13 (117) (2020) 7063-7070.

What is claimed is:

1. A film comprising a perovskite and a polymer, wherein the perovskite and the polymer are configured to form a plurality of elongated pores.

2. The film of claim 1, wherein the film comprises two opposed major surfaces interconnected by the pores and wherein the pores are at least partially vertically aligned to the two opposed major surfaces of the film.

3. The film of claim 1, wherein the pores deform when a force is applied to a major surface of the film.

4. The film of claim 1, wherein the pores are about 20 µm to 25 µm in length.

5. The film of claim 1, wherein the pores are about 3 µm to about 5 µm in diameter.

6. The film of claim 1, wherein the perovskite comprises a hybrid halide perovskite.

7. The film of claim 1, wherein the film comprises the polymer in a crystalline β-phase.

8. The film of claim 1, wherein the film comprises the perovskite in a mass ratio of about 10 wt. % to about 30 wt. %.

9. The film of claim 1, wherein the film comprises the polymer in a mass ratio of about 10 wt. % to about 15 wt. %.

10. A piezoelectric nanogenerator comprising:
a. the film defined in claim 1;
b. a first electrode, and
c. a second electrode,
wherein the film is in electrical contact with the first electrode and the second electrode.

11. An aircraft structural health monitoring system incorporating the piezoelectric nanogenerator defined in claim 10.

12. A self-powered device incorporating the piezoelectric nanogenerator defined in claim 10.

13. The self-powered device of claim 12, wherein the device is a wearable electronic device, a medical diagnostic device, or an implantable device.

14. A process for producing a film comprising the steps of:
a. preparing a first solution by adding a polymer to a first solvent;
b. preparing a second solution by adding a perovskite to a second solvent;
c. homogenously mixing the first solution with the second solution to create a mixture; and
d. maintaining the mixture at a substantially constant temperature to crystalize the polymer and the perovskite.

15. A composite film comprising a substrate and a plurality of piezoelectric nanoparticles, wherein the substrate and the nanoparticles are configured to form a plurality of pores and wherein the composite comprises two opposed major surfaces interconnected by the pores.

16. The composite film of claim 15, wherein the substrate is a polymer.

17. The composite film of claim 15, wherein the piezoelectric nanoparticles comprise a perovskite.

18. The composite film of claim 15, wherein the pores are elongated.

19. The composite film of claim 15, wherein the piezoelectric nanoparticles comprise zinc oxide (ZnO) nanoparticles.

20. A piezoelectric nanogenerator comprising:
a. the composite film defined in claim 15;
b. a first electrode, and
c. a second electrode,
wherein the film is in electrical contact with the first electrode and the second electrode.
